(19) United States
(12) Patent Application Publication
(10) Pub. No.: US 2026/0038598 A1
(43) Pub. Date: Feb. 5, 2026

(54) MEMORIES CONFIGURED TO ERASE MEMORY CELLS FROM A SUBSET OF STRINGS OF SERIES-CONNECTED MEMORY CELLS OF A BLOCK OF MEMORY CELLS

(71) Applicant: MICRON TECHNOLOGY, INC., Boise, ID (US)

(72) Inventor: Andrew Bicksler, Nampa, ID (US)

(73) Assignee: MICRON TECHNOLOGY, INC., Boise, ID (US)

(21) Appl. No.: 19/272,086

(22) Filed: Jul. 17, 2025

Related U.S. Application Data
(60) Provisional application No. 63/677,448, filed on Jul. 31, 2024.

(51) Int. Cl. G11C 16/14

(52) U.S. Cl. CPC G11C 16/14

(57) ABSTRACT

Memories might include a controller configured to cause the memory to apply a first voltage level to each data line of a plurality of data lines, generate gate-induced drain leakage (GIDL) from a selected data line to a channel structure of a respective string of series-connected memory cells, inhibit generation of GIDL from an unselected data line to a channel structure of a respective string of series-connected memory, and apply a second voltage level to a selected access line connected to a respective memory cell of each of the strings of series-connected memory cells, wherein the second voltage level is configured to remove charge from its respective memory cell of the respective string of series-connected memory cells of the selected data line and is configured to inhibit removal of charge from its respective memory cell of the respective string of series-connected memory cells of the unselected data line.

This application claims the benefit of U.S. Provisional Application No. 63/677,448, filed on Jul. 31, 2024, hereby incorporated herein in its entirety by reference.

### TECHNICAL FIELD

The present disclosure relates generally to integrated circuits, and, in particular, in one or more embodiments, the present disclosure relates to memories configured to erase memory cells from a subset of strings of series-connected memory cells of a block of memory cells.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of data-storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor might be connected to a common source, while each drain select transistor might be connected to a data line, such as a column bit line. Variations using more than one select gate between a string of memory cells and the common source, and/or between the string of memory cells and the data line, are known.

In programming memory, memory cells might be programmed as what are often termed single-level cells (SLC). SLC might use a single memory cell to represent one digit (e.g., one bit) of data. For example, in SLC, a Vt of 2.5V or higher might indicate a programmed memory cell (e.g., representing a logical 0) while a Vt of −0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

Memory cells are typically erased before they are programmed to a desired data state. For example, memory cells of a particular block of memory cells might first be erased and then selectively programmed. For a NAND array, a block of memory cells is typically erased by grounding all of the access lines (e.g., word lines) in the block and applying an erase voltage level to the channel regions of the memory cells (e.g., through data lines and source connections) in order to remove charges that might be stored on data-storage structures (e.g., floating gates or charge traps) of the block of memory cells. Typical erase voltage levels might be on the order of 20V or more before completion of an erase operation.

### BRIEF DESCRIPTION OF THE DRAWINGS

FIG. 1 is a simplified block diagram of a memory in communication with a processor as part of an electronic system, according to an embodiment.

FIGS. 2A-2C are schematics of portions of an array of memory cells as could be used in a memory of the type described with reference to FIG. 1.

FIGS. 3A-3B are conceptual depictions of a block of memory cells of a conventional memory.

FIGS. 4A-4B are conceptual depictions of a block of memory cells of a memory in accordance with embodiments.

FIGS. 5A-5B are schematics of a simplified block of memory cells taken from orthogonal planes that could be used with embodiments.

FIG. 6 is a flowchart of a method of operating a NAND memory in accordance with an embodiment.

FIGS. 7A-7C are flowcharts of methods of operating a NAND memory in accordance with additional embodiments for use in conjunction with the method of FIG. 6.

FIG. 8 is a flowchart of a method of operating a NAND memory in accordance with another embodiment.

FIG. 9 is a flowchart of a method of operating a NAND memory in accordance with an additional embodiment for use in conjunction with the method of FIG. 8.

FIGS. 10A-10B are a flowchart of a method of operating a NAND memory in accordance with a further embodiment.

FIG. 11 is a schematic of series-connected transistors for use with embodiments.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized, and structural, logical, and electrical changes might be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by an electrically conductive path unless otherwise apparent from the context.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

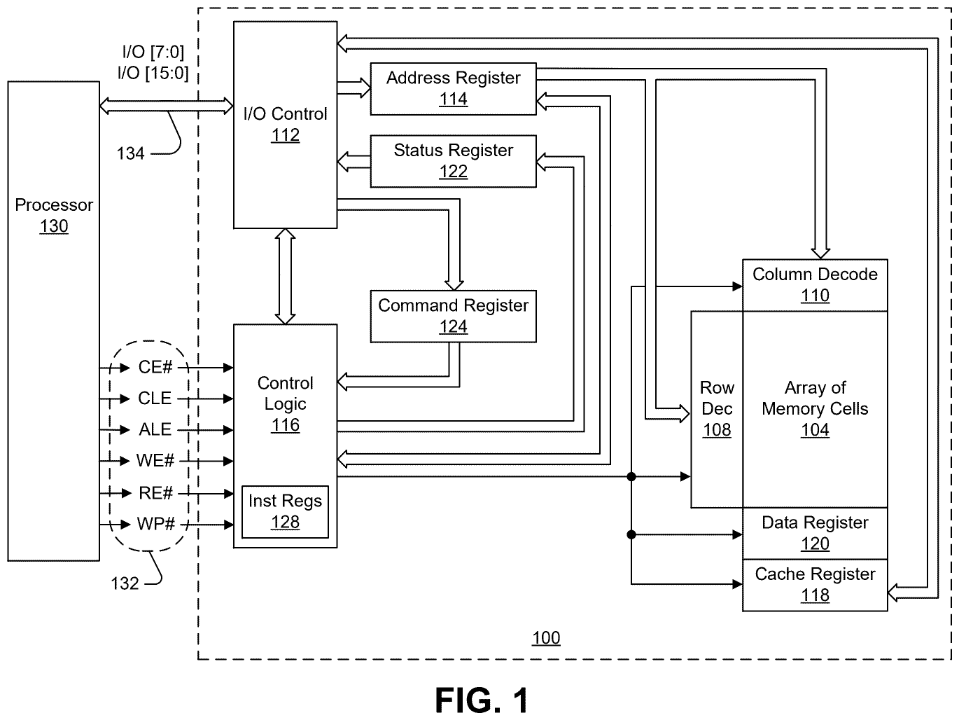

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two target data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses, and data to the memory device 100 as well as output of data and status information from the memory device 100. An address register 114 is in communication with I/O control circuitry 112, as well as row decode circuitry 108 and column decode circuitry 110, to latch the address signals prior to decoding. A command register 124 is in communication with I/O control circuitry 112 and control logic 116 to latch incoming commands.

An internal controller (e.g., the control logic 116 internal to the memory device 100) controls access to the array of memory cells 104 in response to the commands and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

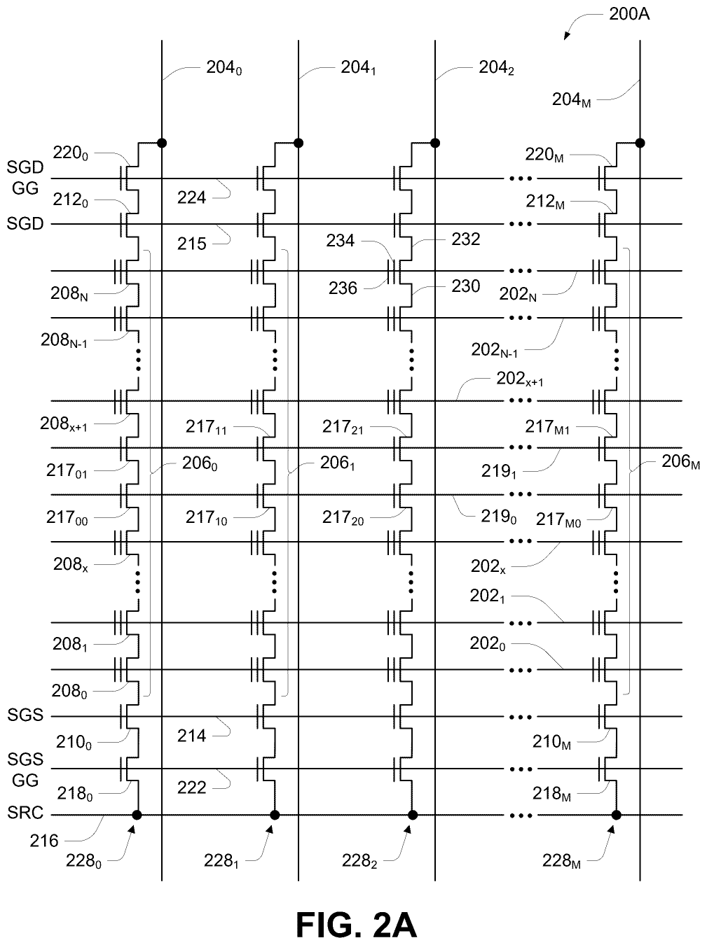

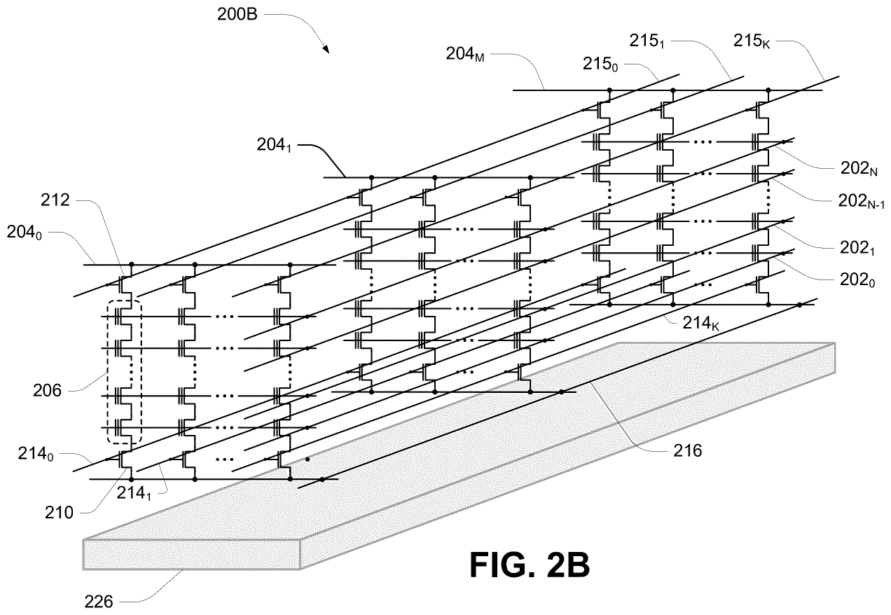

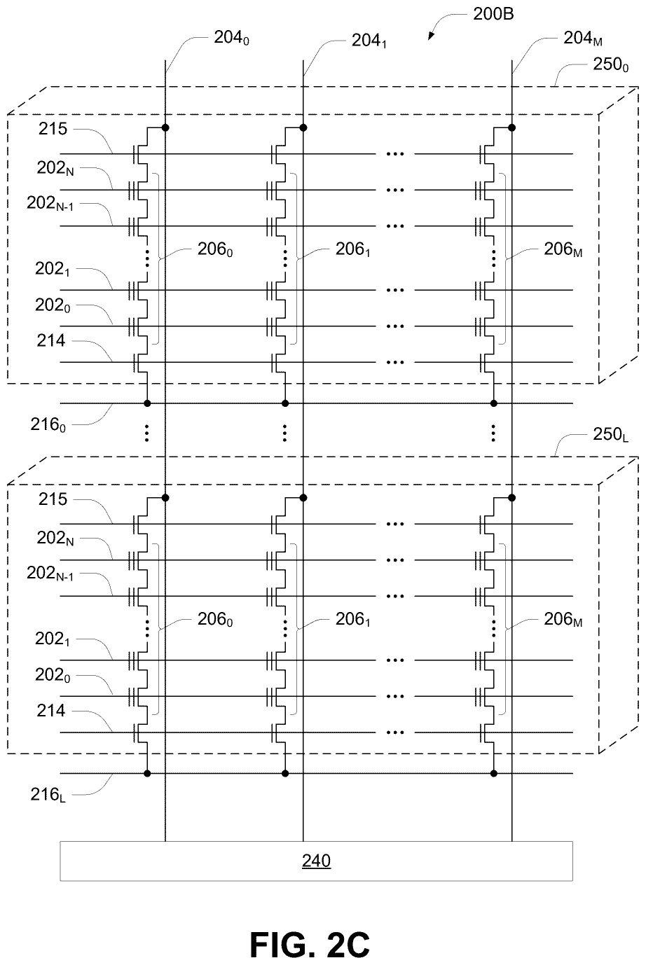

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, e.g., word lines, such as access lines 202₀ to 202_{N}, and data lines, e.g., bit lines, such as data lines 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. However, even if using a same structure as the memory cells 208, the select gates 210 and 212 would not be considered to be memory cells as they are not configured to store data accessible to a user of the memory. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218_{M} might be referred to as source GG gates. The source GG gates 218₀ to 218_{M} might each be connected (e.g., directly connected) to the common source 216 (e.g., through a corresponding conductive node 228₀ to 228_{M}, respectively), and selectively connected to their respective NAND strings 206₀ to 206_{M}, respectively Alternatively, a source select gate 210 and its GG gate 218 might represent a single gate, e.g., connected (e.g., directly connected) to the common source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218_{M} might be commonly connected to a control line 222, such as an SGS GG control line, and GG gates 220₀ to 220_{M} might be commonly connected to a control line 224, such as an SGD GG control line. Although depicted as traditional field-effect transistors, the GG gates 218 and 220 might utilize a structure similar to (e.g., the same as) the memory cells 208. However, even if using a same structure as the memory cells 208, the GG gates 218 and 220 would not be considered to be memory cells as they are not configured to store data accessible to a user of the memory. The GG gates 218 and 220 might each represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel region of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 212₀ of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

Intermediate gates 217 (e.g., intermediate gates 217_{J0} and 217_{J1}, where J is any integer value from 0 to M) might be connected in series between different subsets of the memory cells 208 of a NAND string 206. For example, a source of the intermediate gate 217₀₀ of FIG. 2A might be connected to a drain of the memory cell 208ₓ of the NAND string 206₀, a source of the intermediate gate 217₀₁ of FIG. 2A might be connected to a drain of the intermediate gate 217₀₀, and a drain of the intermediate gate 217₀₁ of FIG. 2A might be connected to a source of the memory cell 208ₓ₊₁ of the NAND string 206₀. Control gates of the intermediate gates 217_{J0} and 217_{J1} of FIG. 2A might be connected to select lines 219₀ and 219₁, respectively. While only two intermediate gates 217 are depicted in each NAND string 206, fewer or additional intermediate gates 217 could be used. Although depicted as traditional field-effect transistors, the intermediate gates 217 might utilize a structure similar to (e.g., the same as) the memory cells 208. The intermediate gates 217 facilitate dividing the NAND strings 206 into two decks of memory cells, e.g., a bottom deck of memory cells containing memory cells 208₀ to 208ₓ, and a top deck of memory cells containing memory cells 208ₓ₊₁ to 208_{N}. Even if using a same structure as the memory cells 208, the intermediate gates 217 would not be considered to be memory cells as they are not configured to store data accessible to a user of the memory.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include conductive and/or dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃ to 204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given word line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. The three-dimensional NAND memory array 200B might incorporate vertical structures which might include semiconductor pillars, which might be solid or hollow, where a portion of a pillar might act as a channel region of the memory cells of NAND strings 206, e.g., a region through which current might flow when a memory cell, e.g., a field-effect transistor, is activated. The NAND strings 206 might be each selectively connected to a data line 204₀ to 204_{M} by a select gate 212 (e.g., that might be drain select transistors, commonly referred to as select gate drain) and to a common source 216 by a select gate 210 (e.g., that might be source select transistors, commonly referred to as select gate source). Multiple NAND strings 206 might be selectively connected to the same data line 204. Subsets of NAND strings 206 can be connected to their respective data lines 204 by biasing the select lines 215₀ to 215_{K} to selectively activate particular select gates 212 each between a NAND string 206 and a data line 204. Multiple NAND strings 206 might be selectively connected to the common source 216. Subsets of NAND strings 206 can be connected to the common source 216 by biasing the select lines 214₀ to 214_{K} to selectively activate particular select gates 212 each between a NAND string 206 and a data line 204. For some embodiments, the select lines 214 might be commonly connected to receive the same control signal(s). Each access line 202 might be connected to multiple rows of memory cells of the memory array 200B. Rows of memory cells that are commonly connected to each other by a particular access line 202 might collectively be referred to as tiers. For clarity, the GG gates 218 and 220, and the intermediate gates 217, are not depicted in FIG. 2B.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation remains as a matter of convenience.

FIG. 2C is a further schematic of a portion of an array of memory cells 200C as could be used in a memory of the type described with reference to FIG. 1, e.g., as a portion of array of memory cells 104. Like numbered elements in FIG. 2C correspond to the description as provided with respect to FIG. 2A. Array of memory cells 200C might include strings of series-connected memory cells (e.g., NAND strings) 206, access (e.g., word) lines 202, data (e.g., bit) lines 204, select lines 214 (e.g., source select lines), select lines 215 (e.g., drain select lines) and common source 216 as depicted in FIG. 2A. For clarity, the GG gates 218 and 220, and the intermediate gates 217, are not depicted in FIG. 2C.

FIG. 2C depicts groupings of NAND strings 206 into blocks of memory cells 250, e.g., blocks of memory cells 250₀ to 250_{L}. Each block of memory cells 250 might represent those NAND strings 206 selectively connected to a common source. The common source 216₀ for the block of memory cells 250₀ might be a different source than (e.g., isolated from) the common source 216_{L} for the block of memory cells 250_{L}. Access lines 202 and select lines 214 and 215 of one block of memory cells 250 might have no direct connection to access lines 202 and select lines 214 and 215, respectively, of any other block of memory cells of the blocks of memory cells 250₀ to 250_{L}. The array of memory cells 200A might represent a portion of a block of memory cells 250 of the array of memory cells 200C, e.g., a sub-block of memory cells selectively connected to the data lines 204₀ to 204_{M} in response to a same select line 215 or in response to a set of select lines 215, for example. In addition, the array of memory cells 200B might represent a block of memory cells 250 of the array of memory cells 200C, for example.

Blocks of memory cells 250 might contain one or more groupings of memory cells 208 that might be erased together in a single erase operation. Such groupings of memory cells 208 will be referred to herein as erase blocks. In conventional memories, the entirety of a block of memory cells 250 might correspond to an erase block. For various embodiments, a block of memory cells 250 might correspond to two or more erase blocks, each corresponding to a subset (e.g., proper subset) of NAND strings 206 of the block of memory cells 250. The erase blocks of memory cells might contain memory cells of the proper subset of NAND strings 206 for all decks of memory cells, or only a single deck of memory cells.

The data lines 204₀ to 204_{M} might be connected (e.g., selectively connected) to a buffer portion 240, which might be a portion of a page buffer of the memory. The buffer portion 240 might correspond to a memory plane (e.g., the set of blocks of memory cells 250₀ to 250_{L}.). The buffer portion 240 might include sense circuits (not shown in FIG. 2C) for sensing data values indicated on respective data lines 204.

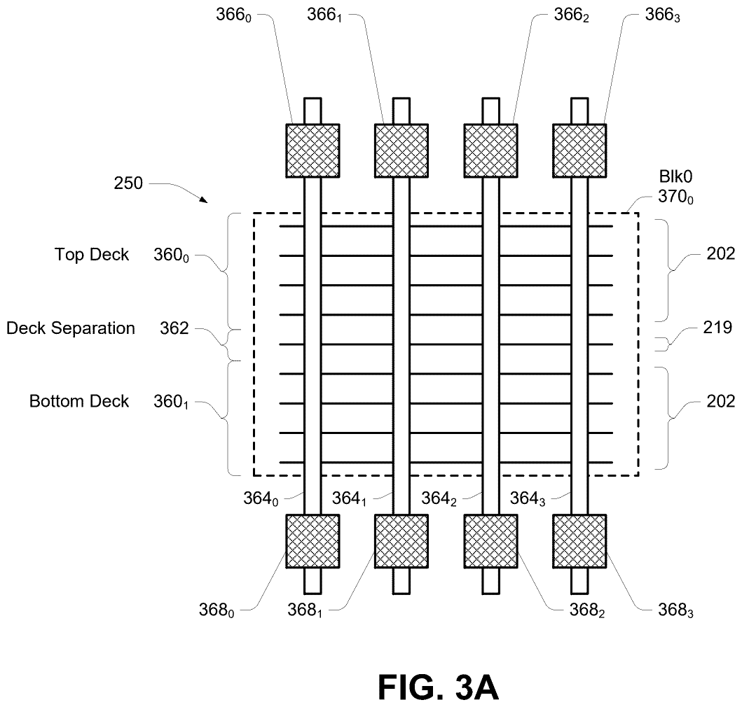

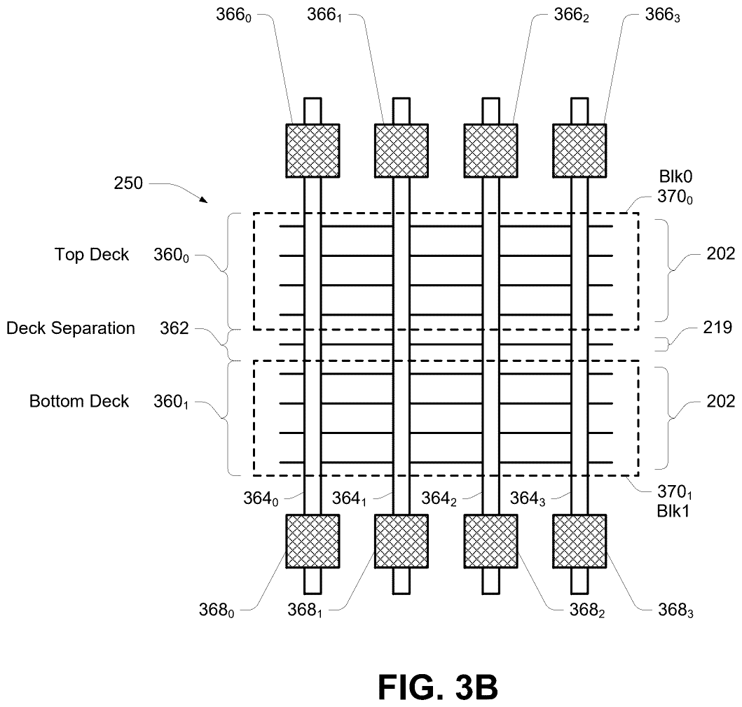

FIG. 3A is a conceptual depiction of a block of memory cells 250 of a conventional memory. The block of memory cells 250 is depicted to have a top deck of memory cells 360₀ and a bottom deck of memory cells 360₁ with an intervening deck separation 362. The top deck of memory cells 360₀ might correspond to memory cells 208 having control gates connected to one or more access lines 202, e.g., the access lines 202ₓ₊₁ to 202_{N} of FIG. 2A. The bottom deck of memory cells 360₁ might correspond to memory cells 208 having control gates connected to one or more other access lines, e.g., the access lines 202₀ to 202ₓ of FIG. 2A. The intervening deck separation 362 might correspond to intermediate gates 217 connected to one or more select lines 219, e.g., the select lines 219₀ to 219₁ of FIG. 2A.

The block of memory cells of FIG. 3A is further depicted to have channel structures 364. The channel structures 364 might correspond to channels of the memory cells 208 of the block of memory cells 250. For example, a memory cell 208 might be formed at each intersection of an access line 202 and a channel structure 364. The channel structures 364 might further correspond to channels of the intermediate gates 217 of the block of memory cells 250, e.g., an intermediate gate 217 might be formed at each intersection of a control line 219 and a channel structure 364. The block of memory cells of FIG. 3A is further depicted to have drain-side selection devices 366₀ to 366₃ for selectively connecting the channel structures 364₀ to 364₃, respectively, to respective data lines 204 (not depicted in FIG. 3A). The drain-side selection devices 366 might each correspond to one or more select gates 212 and/or one or more GG gates 220. The block of memory cells 250 of FIG. 3A is further depicted to have source-side selection devices 368₀ to 368₃ for selectively connecting the channel structures 364₀ to 364₃, respectively, to the common source 216 (not depicted in FIG. 3A). The source-side selection devices 368 might each correspond to one or more select gates 210 and/or one or more GG gates 218.

Select gates 212 of the drain-side selection devices 366 might be connected to one or more select lines, such as select line 215 of FIG. 2A. A select gate 212 of one drain-side selection device 366 corresponding to one channel structure 364 might have a control gate connected to a different select line 215 than a control gate of a corresponding select gate 212 for each drain-side selection device 366 corresponding to each remaining channel structure 364. For example, a select gate 212 of the drain-side selection device 366₀ might be connected to one select line 215, a corresponding select gate 212 of the drain-side selection device 366₁ might be connected to a different select line 215, and so on.

GG gates 220 of the drain-side selection devices 366 might be connected to one or more control lines, such as control line 224 of FIG. 2A. A GG gate 220 of one drain-side selection device 366 corresponding to one channel structure 364 might have a control gate connected to a different control line 224 than a control gate of a corresponding GG gate 220 for each drain-side selection device 366 corresponding to each remaining channel structure 364. For example, a GG gate 220 of the drain-side selection device 366₀ might be connected to one control line 224, a corresponding GG gate 220 of the drain-side selection device 366₁ might be connected to a different control line 224, and so on.

Select gates 210 of the source-side selection devices 368 might be connected to one or more select lines, such as select line 214 of FIG. 2A. A select gate 210 of one source-side selection device 368 corresponding to one channel structure 364 might have a control gate connected to a different select line 214 that a control gate of a corresponding select gate 210 for each source-side selection device 368 corresponding to each remaining channel structure 364. For example, a select gate 210 of the source-side selection device 368₀ might be connected to one select line 214, a corresponding select gate 210 of the source-side selection device 368₁ might be connected to a different select line 214, and so on.

GG gates 218 of the source-side selection devices 368 might be connected to one or more control lines, such as control line 222 of FIG. 2A. A GG gate 218 of one source-side selection device 368 corresponding to one channel structure 364 might have a control gate connected to a different control line 222 than a control gate of a corresponding GG gate 218 for each source-side selection device 368 corresponding to each remaining channel structure 364. For example, a GG gate 218 of the source-side selection device 368₀ might be connected to one control line 222, a corresponding GG gate 218 of the source-side selection device 368₁ might be connected to a different control line 222, and so on.

The block of memory cells 250 of FIG. 3A might be configured to have a single erase block 370, e.g., erase block 370₀ or Blk0, such that all memory cells of the block of memory cells 250 might be erased in a single erase operation performed by the memory.

FIG. 3B is a conceptual depiction of a block of memory cells 250 of another conventional memory. Like numbered elements in FIG. 3B correspond to the description as provided with respect to FIG. 3A. Unlike the block of memory cells 250 of FIG. 3A, the block of memory cells 250 of FIG. 3B might be configured to have two erase blocks 370, e.g., erase block 370₀ or Blk0, and erase block 370₁ or Blk1, such that the memory cells of the top deck of memory cells 360₀ might be erased independently of the memory cells of the bottom deck of memory cells 360₁, and vice versa, during a single erase operation performed by the memory. Erasing the memory cells of the erase block 370₀ might be performed by electrically floating the access lines 202 corresponding to the erase block 370₁ while increasing the voltage level of the channel structures 364 to an erase voltage level and while applying a second voltage level, e.g., ground or other low voltage level, to the access lines 202 of the erase block 370₀. By floating the access lines 202 corresponding to the erase block 370₁, their voltage levels might be allowed to increase through capacitive coupling such that they would be inhibited from erasure. The second voltage level applied to a control gate of a memory cell is a voltage level configured to remove charge from the data-storage structure of the memory cell while its channel is at the erase voltage level. Note that while a same second voltage level might be applied to each access line 202 corresponding to memory cells 208 selected for an erase operation, a second voltage level for one access line 202 corresponding to memory cells 208 selected for the erase operation might be different than a second voltage level for a different access line 202 corresponding to memory cells 208 selected for the erase operation due to differing operational characteristics corresponding to the different access lines 202. Erasing the memory cells of the erase block 370₁ can be performed in a similar manner, e.g., by electrically floating the access lines 202 corresponding to the erase block 370₀ while increasing the voltage level of the channel structures 364 to an erase voltage level (Vera) and while applying a second voltage level to the access lines 202 of the erase block 370₁. During erasure of either erase block 370, the control lines 219 of the deck separation 362 might also be electrically floating.

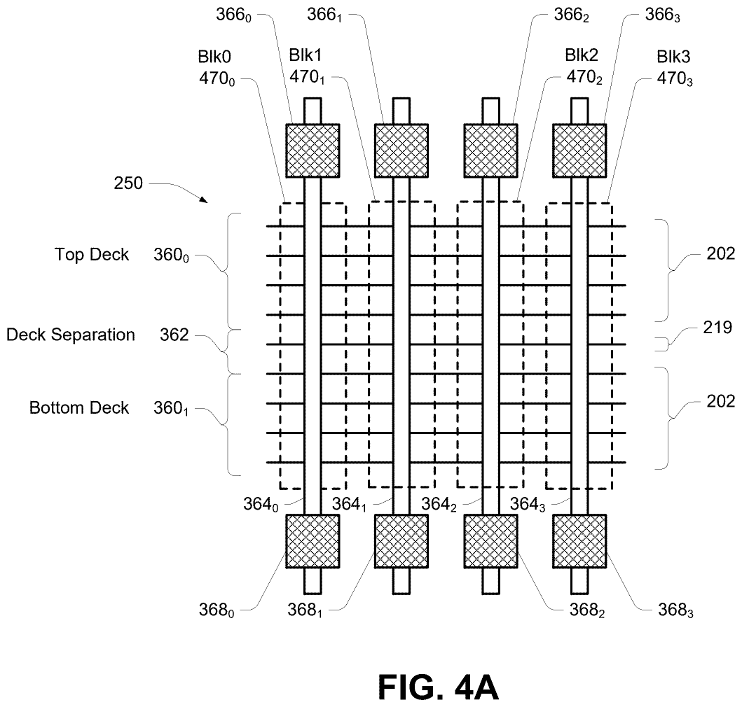

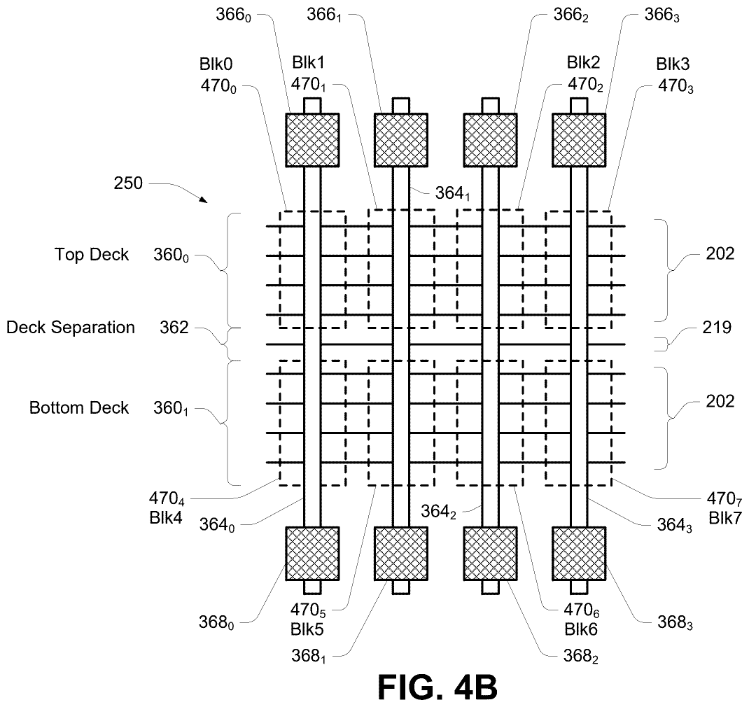

FIG. 4A is a conceptual depiction of a block of memory cells 250 of a memory in accordance with an embodiment. Like numbered elements in FIG. 4A correspond to the description as provided with respect to FIG. 3A. Unlike the block of memory cells 250 of FIG. 3A, the block of memory cells 250 of FIG. 4A might be configured to have four erase blocks 470, e.g., erase block 470₀ or Blk0, erase block 470₁ or Blk1, erase block 470₂ or Blk2, and erase block 470₃ or Blk3, that each might be erased independently during a single erase operation performed by the memory. Unlike the erase blocks 370 of FIGS. 3A and 3B, which each contain memory cells from each NAND string 206 of its block of memory cells 250, the erase blocks 470 of FIG. 4A might contain memory cells of only a proper subset of NAND strings 206 (e.g., at least one and fewer than all NAND strings 206) of its block of memory cells 250.

Erasing the memory cells of the erase block 470₀ might be performed by applying an erase voltage level (Vera) to the data lines 204 corresponding to the channel structures 364₀ to 364₃, e.g., all data lines 204 of the block of memory cells 250, applying one or more first voltage levels to the control gates of the drain-side selection devices 366₀ configured to generate GIDL into the channel structure 364₀ from its corresponding data line 204, and, optionally, applying one or more second voltage levels to the control gates of the source-side selection devices 368₀ configured to generate GIDL into the channel structure 364₀ from the common source 216. The one or more first voltage levels, and the one or more second voltage levels, might each be lower than the erase voltage level. For example, for an erase voltage level of 20V, a first or second voltage level of 12V might be used. The one or more first voltage levels applied to the control gates of the drain-side selection devices 366₀ might be the same as or different than the one or more second voltage levels applied to the control gates of the source-side selection devices 368₀. For embodiments sharing select lines 214 and/or control lines 222, one or more third voltage levels might be applied to the control gates of the source-side selection devices 368₀ to 368₃ configured to inhibit generation of GIDL into the channel structures 364₀ to 364₃. The one or more third voltage levels might include voltage levels higher than or equal to the erase voltage level, or otherwise configured to inhibit generation of GIDL from the common source 216.

To inhibit erasure of the other erase blocks 470₁ to 470₃, one or more of the third voltage levels might be applied to the control gates of the source-side selection devices 368₁ to 368₃ configured to inhibit generation of GIDL into the channel structures 364₁ to 364₃ from the common source 216, and one or more fourth voltage levels might be applied to the control gates of the drain-side selection devices 366₁ to 366₃ configured to inhibit generation of GIDL into the channel structures 364₁ to 364₃ from the corresponding data lines 204. The one or more fourth voltage levels might include voltage levels higher than or equal to the erase voltage level, or otherwise configured to inhibit generation of GIDL from the data lines. For example, for an erase voltage level of 20V, a third or fourth voltage level of 22V might be used. The one or more third voltage levels applied to the control gates of the source-side selection devices 368₁ to 368₃ might be the same as or different than the one or more fourth voltage levels applied to the control gates of the drain-side selection devices 366₁- to 366₃.

While applying the erase voltage level to the data lines 204, one or more fifth voltage levels, e.g., voltage levels at or near Vss, ground or 0V, might be applied to the access lines 202. In general, a gate-to-body voltage difference between the erase voltage level applied to the data lines 204 and the fifth voltage level(s) applied to the access lines 202 might be configured to remove charge from data-storage structures of memory cells 208 formed around the channel structure 364₀ configured to receive the GIDL current, e.g., receiving the erase voltage level. Conversely, for channel structures 364₁ to 364₃ not configured to receive the GIDL current, e.g., isolated from the erase voltage level, the gate-to-body voltage difference might be insufficient to effect erasure of their corresponding memory cells. Note that the magnitudes of the individual voltage levels can be altered, provided that a voltage differential between the erase voltage level applied to the data lines 204 and each of the fifth voltage levels applied to the access lines 202 is configured to remove charge from data-storage structures of the memory cells 208 formed around channel structures 364 configured to receive the erase voltage level, and configured to inhibit removal of charge from data-storage structures of the memory cells 208 formed around channel structures 364 configured to be isolated from the erase voltage level.

Note that while each access line 202 corresponding to memory cells 208 selected for an erase operation might receive a same voltage level, one or more access lines 202 corresponding to memory cells 208 selected for the erase operation might receive different voltage levels than one or more other access lines 202 corresponding to memory cells 208 selected for the erase operation due to differing operational characteristics corresponding to the different access lines 202.

For embodiments having deck separation 362, such as depicted in FIG. 4A, the control lines 219 might receive respective sixth voltage levels (e.g., lower than the erase voltage level and higher than the fifth voltage levels) configured to inhibit erasure of its corresponding intermediate gates 217 whether or not its channel structure 364 receives the erase voltage level. For example, a voltage level of Vera/2 might be applied to the control lines 219.

Although the block of memory cells 250 of FIG. 4A is depicted to have two decks of memory cells 360, the block of memory cells 250 might have fewer or more decks of memory cells 360. Similarly, although the block of memory cells 250 of FIG. 4A is depicted to have four erase blocks 470, the block of memory cells 250 might have fewer or more erase blocks 470. For example, at an upper limit, the block of memory cells 250 might have a number of erase blocks 470 equal to a number of data lines 204 of the block of memory cells 250. As another example, the block of memory cell 250 of FIG. 4A might have two erase blocks 470, with a first erase block 470 corresponding to channel structures 364₀ and 364₁, and a second erase block 470 corresponding to channel structures 364₂ and 364₃.

FIG. 4B is a conceptual depiction of a block of memory cells 250 of a memory in accordance with another embodiment. Like numbered elements in FIG. 4B correspond to the description as provided with respect to FIG. 3A. Unlike the block of memory cells 250 of FIG. 3A, the block of memory cells 250 of FIG. 4B might be configured to have eight erase blocks 470, e.g., erase block 470₀ or Blk0, erase block 470₁ or Blk1, erase block 470₂ or Blk2, erase block 470₃ or Blk3, erase block 470₄ or Blk4, erase block 470₅ or Blk5, erase block 470₆ or Blk6, and erase block 470₇ or Blk7, that each might be erased independently during a single erase operation performed by the memory. Unlike the erase blocks 370 of FIGS. 3A and 3B, which each contain memory cells from each NAND string 206 of its block of memory cells 250, the erase blocks 470 of FIG. 4B might contain memory cells of only a proper subset of NAND strings 206 (e.g., at least one and fewer than all NAND strings 206) of its block of memory cells 250. The erase blocks 470 of FIG. 4B might further contain memory cells of only a proper subset of decks of memory cells 360 (e.g., at least one and fewer than all decks of memory cells 360) of its block of memory cells 250. The erase voltage level, first voltage levels, second voltage levels, third voltage levels, fourth voltage levels, fifth voltage levels, and sixth voltage levels discussed with reference to FIG. 4B will have the same meaning as used with reference to FIG. 4A.

Erasing the memory cells of the erase block 470₀ might be performed by applying an erase voltage level (Vera) to the data lines 204 corresponding to the channel structures 364₀ to 364₃, e.g., all data lines 204 of the block of memory cells 250, and applying one or more first voltage levels to the control gates of the drain-side selection devices 366₀ configured to generate GIDL into the channel structure 364₀ from its corresponding data line 204.

To inhibit erasure of the other erase blocks 470₁ to 470₇, one or more of the third voltage levels might be applied to the control gates of the source-side selection devices 368₀ to 368₃ configured to inhibit generation of GIDL into the channel structures 364₆ to 364₃ from the common source 216, and one or more of the fourth voltage levels might be applied to the control gates of the drain-side selection devices 366₁ to 366₃ configured to inhibit generation of GIDL into the channel structures 364₁ to 364₃ from the corresponding data lines 204.

While applying the erase voltage level to the data lines 204, one or more of the fifth voltage levels might be applied to the access lines 202 of the top deck of memory cells 360₀, and access lines 202 of the bottom deck of memory cells 360₁ might be electrically floated or might receive one or more of the sixth voltage levels. The control lines 219 might receive one or more seventh voltage levels configured to isolate memory cells of the top deck of memory cells 360₀ from memory cells of the bottom deck of memory cells 360₁.

Other erase blocks of the top deck of memory cells 360₀ might be erased in a similar manner, with an erase block 470 of the top deck of memory cells 360₀ selected for erasure (e.g., any erase block 470₀ to 470₃) configured to receive GIDL current from its corresponding data line 204, with each remaining erase block 470 of the top deck of memory cells 360₀ configured to be inhibited from receiving GIDL current from its corresponding data line 204, and with each erase block 470 of the bottom deck of memory cells 360₁ (e.g., each erase block 470₄ to 470₇) configured to be inhibited from receiving GIDL current from the common source 216.

Similarly, erase blocks of the bottom deck of memory cells 360₁ might be erased by configuring each erase block 470 of the top deck of memory cells 360₀ (e.g., each erase block 470₀ to 470₃) to be inhibited from receiving GIDL current from its corresponding data line 204, configuring a selected erase block 470 of the bottom deck of memory cells 360₁ (e.g., any erase block 470₄ to 470₇) to receive GIDL current from the common source 216, and configuring each remaining erase block 470 of the bottom deck of memory cells 360₁ to be inhibited from receiving GIDL current from the common source 216.

Although the block of memory cells 250 of FIG. 4B is depicted to have eight erase blocks 470, the block of memory cells 250 might have fewer or more erase blocks 470. For example, at an upper limit, the block of memory cells 250 might have a number of erase blocks 470 equal to a number of data lines 204 of the block of memory cells 250 times two. As another example, the block of memory cell 250 of FIG. 4B might have four erase blocks 470, with a first erase block 470 corresponding to the top deck of memory cells 360₀ of the channel structures 364₀ and 364₁, a second erase block 470 corresponding to the top deck of memory cells 360₀ of the channel structures 364₂ and 364₃, a third erase block 470 corresponding to the bottom deck of memory cells 360₁ of the channel structures 364₀ and 364₁, and a fourth erase block 470 corresponding to the bottom deck of memory cells 360₁ of the channel structures 364₂ and 364₃.

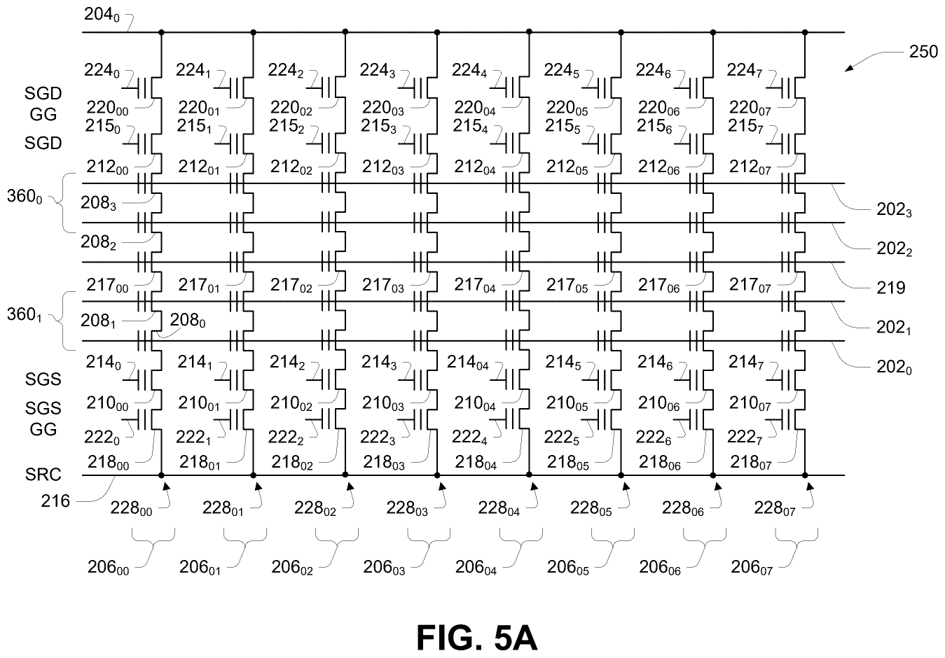

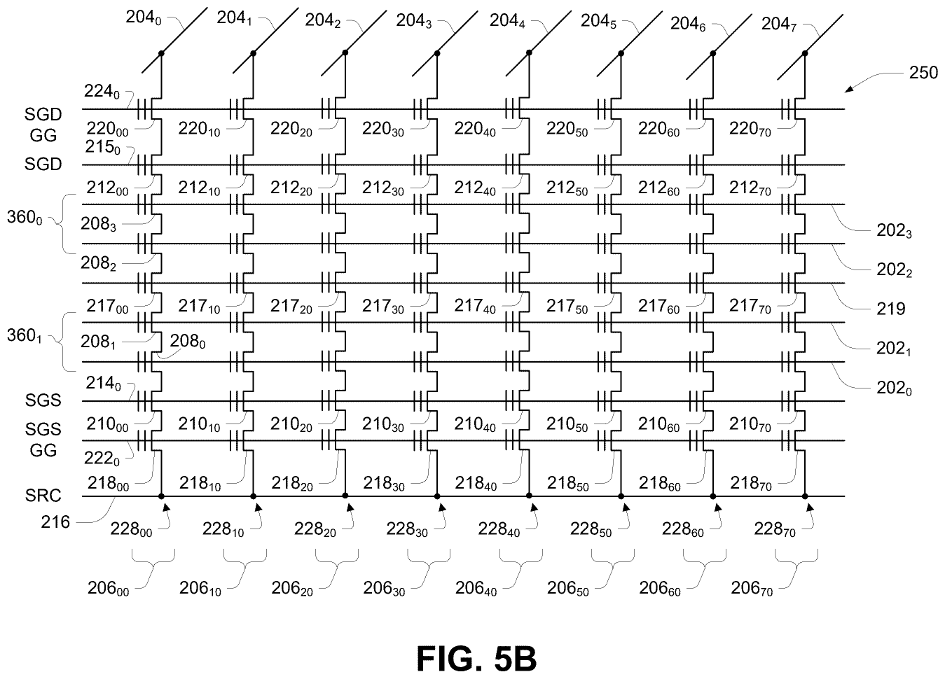

FIGS. 5A-5B are schematics of a simplified block of memory cells 250 taken from orthogonal planes that could be used with embodiments. The block of memory cells 250 of FIGS. 5A-5B includes access lines, such as access lines 202₀ to 202₃, and data lines 204, such as data lines 204₀ to 204₇. The block of memory cells 250 of FIGS. 5A-5B further includes strings of series-connected memory cells, e.g., NAND strings 206₀₀ to 206₀₇ depicted in FIG. 5A and NAND strings 206₀₀ to 206₇₀ depicted in FIG. 5B. Each NAND string 206 is selectively connected to the common source 216 (e.g., through a corresponding conductive node 228), and further selectively connected to a corresponding data line 204. The block of memory cells 250 of FIGS. 5A-5B further includes deck separation, e.g., intermediate select gates 217. Each intermediate select gate 217 corresponds to a respective NAND string 206. Each control line 224₀ to 224₇ and each select line 215₀ to 215₇ might correspond to a respective set of NAND string 206.

The memory cells 208 of each NAND string 206 might be connected in series between a source select gate 210 and a drain select gate 212. Source select gates 210 each might be connected to a respective select line 214₀ to 214₇, referred to as source select lines (SGS). Drain select gates 212 each might be connected to a respective select line 215₀ to 215₇, referred to as drain select lines (SGD). Although depicted as having a same structure as the memory cells 208, the select gates 210 and 212 might utilize a structure of traditional field-effect transistors. The select gates 210 and 212 each might represent a plurality of select gates connected in series, with each select gate in series configured to receive a same or independent control signal. A control gate of each source select gate 210 might be connected to its respective select line 214. A control gate of each drain select gate 212 might be connected to its respective select line 215.

The source select gates 210 for each NAND string 206 might be connected in series between its memory cells 208 and a source GG gate 218. The source GG gates 218 might each be connected (e.g., directly connected) to the common source 216, and selectively connected to their respective NAND strings 206. Alternatively, a source select gate 210 and its source GG gate 218 might represent a single gate, e.g., connected (e.g., directly connected) to the common source 216, and connected (e.g., directly connected) to a respective NAND string 206.

The drain select gates 212 of each NAND string 206 might be connected in series between its memory cells 208 and a drain GG gate 220. The drain GG gates 220 might be connected (e.g., directly connected) to the data line 204, and selectively connected to their respective NAND strings 206. Alternatively, a drain select gate 212 and its drain GG gate 220 might represent a single gate, e.g., connected (e.g., directly connected) to the data line 204, and connected (e.g., directly connected) to a respective NAND string 206.

The source GG gates 218 each might be connected to a respective control line 222₀ to 222₇, referred to as SGS_GG control lines. The drain GG gates 220 each might be connected to a respective control line 224₀ to 224₇, referred to as SGD_GG control lines. Although depicted as having a same structure as the memory cells 208, the GG gates 218 and 220 might utilize a structure of traditional field-effect transistors. The GG gates 218 and 220 might each represent a plurality of GG gates connected in series, with each GG gate in series configured to receive a same or independent control signal.

A source of each source GG gate 218 might be connected to common source 216. The drain of each source GG gate 218 might be connected to a source select gate 210 of the corresponding NAND string 206. For example, the drain of the source GG gate 218₀₀ might be connected to the source of the source select gate 210₀₀ of the corresponding NAND string 206₀₀. Therefore, in cooperation, each source select gate 210 and source GG gate 218 for a corresponding NAND string 206 might be configured to selectively connect that NAND string 206 to the common source 216. A control gate of each source GG gate 218 might be connected to its respective control line 222.

The drain of each drain GG gate 220 might be connected to the data line 204. The source of each drain GG gate 220 might be connected to a drain select gate 212 of the corresponding NAND string 206. For example, the source of the drain GG gate 220₀₀ might be connected to the drain of the drain select gate 212₀₀ of the corresponding NAND string 206₀₀. Therefore, in cooperation, each drain select gate 212 and drain GG gate 220 for a corresponding NAND string 206 might be configured to selectively connect that NAND string 206 to the data line 204. A control gate of each drain GG gate 220 might be connected to its respective control line 224.

Intermediate gates 217 might be connected in series between different portions of the memory cells 208 of a respective NAND string 206. For example, a source of the intermediate gate 217₀₀ of FIGS. 5A-5B might be connected to a drain of the memory cell 208₁ of the NAND string 206₀₀, and a drain of the intermediate gate 217₀₀ of FIGS. 5A-5B might be connected to a source of the memory cell 208₂ of the NAND string 206₀₀. Control gates of the intermediate gates 217 of FIGS. 5A-5B might be connected to select line 219. While only one intermediate gate 217 is depicted in each NAND string 206, additional intermediate gates 217 could be used. Although depicted as having a same structure as the memory cells 208, the intermediate gates 217 might utilize a structure of traditional field-effect transistors. The intermediate gates 217 facilitate dividing the NAND strings 206 into two decks of memory cells.

For some embodiments, the block of memory cells 250 might be divided into more than one erase block. For example, the block of memory cells 250 might have two erase blocks, with NAND strings 206 selectively connected to data lines 204₀ to 204₃ corresponding to one erase block and NAND strings 206 selectively connected to data lines 204₄ to 204₇ corresponding to a second erase block. Although each erase block of this example represents contiguous groupings of NAND strings 206, embodiments might be other than contiguous groupings of NAND strings 206. For example, the erase blocks might be interleaved, with NAND strings 206 selectively connected to data lines 204₀, 204₂, 204₄, and 204₆ corresponding to one erase block and NAND strings 206 selectively connected to data lines 204₁, 204₃, 204₅, and 204₇ corresponding to a second erase block. Other arrangements are also possible.

Other embodiments might have more than two erase blocks. For example, the NAND strings 206 selectively connected to data lines 204₀ and 204₁ might correspond to a first erase block, the NAND strings 206 selectively connected to data lines 204₂ and 204₃ might correspond to a second erase block, the NAND strings 206 selectively connected to data lines 204₄ and 204₅ might correspond to a third erase block, and the NAND strings 206 selectively connected to data lines 204₆ and 204₇ might correspond to a fourth erase block. Alternatively, the erase blocks might be interleaved with NAND strings 206 selectively connected to data lines 204₀ and 204₄ corresponding to a first erase block, the NAND strings 206 selectively connected to data lines 204₁ and 204₅ corresponding to a second erase block, the NAND strings 206 selectively connected to data lines 204₂ and 204₆ corresponding to a third erase block, and the NAND strings 206 selectively connected to data lines 204₃ and 204₇ corresponding to a fourth erase block. In still further embodiments, each erase block might correspond to those NAND strings 206 selectively connected to a single data line 204.

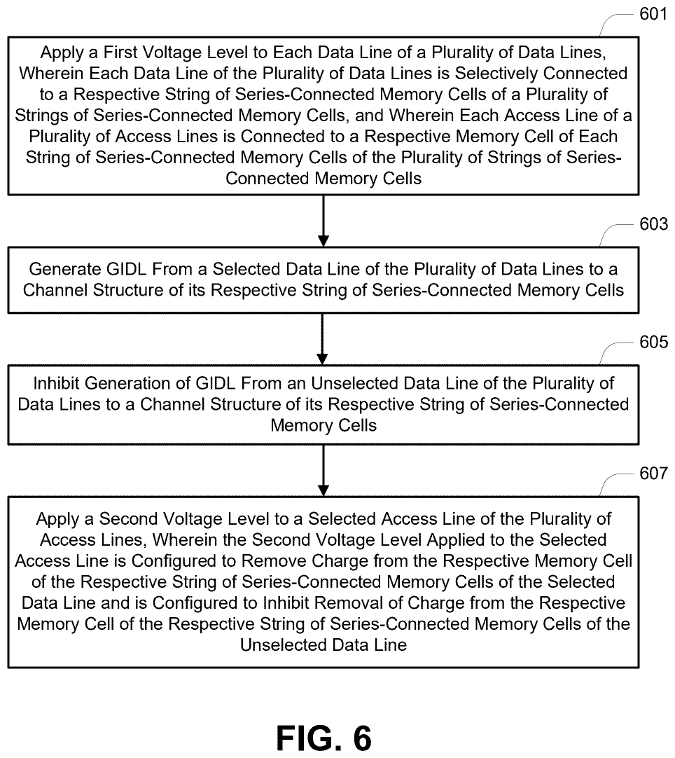

FIG. 6 is a flowchart of a method of operating a NAND memory in accordance with an embodiment. The method might represent actions associated with an access operation, e.g., an erase operation. The method might be in the form of computer-readable instructions, e.g., stored to the instruction registers 128. Such computer-readable instructions might be executed by a controller, e.g., the control logic 116, to cause the relevant components of the memory to perform the method.

At 601, a first voltage level, e.g., an erase voltage level (Vera), might be applied to each data line of a plurality of data lines. The plurality of data lines might include each data line of a block of memory cells. For example, with reference to FIGS. 5A-5B, the plurality of data lines might include data lines 204₀ to 204₇. Each data line of the plurality of data lines might be selectively connected to a respective set of strings of series-connected memory cells of a plurality of strings of series-connected memory cells. For example, with reference to FIG. 5B, the data line 204₀ might be connected to NAND string 206₀₀, the data line 204₁ might be connected to NAND string 206₁₀, and so on. Each access line of a plurality of access lines might be connected to a respective memory cell of each string of series-connected memory cells of the plurality of strings of series-connected memory cells. For example, with reference to FIGS. 5A-5B, the access lines 202₀ to 202₃ are each connected to a respective memory cell of each string of series-connected memory cells of the plurality of strings of series-connected memory cells of the block of memory cells 250. As one example, the first voltage level might be 20V.

At 603, gate-induced drain leakage (GIDL) might be generated from a selected data line of the plurality of data lines to a channel structure of its respective string of series-connected memory cells. GIDL might be generated by creating a high negative voltage differential between the voltage level to the control gate of a drain-side selection device (e.g., one or more of the GG generator gates 220 and/or drain select gates 212) and the first voltage level. As one example, for a first voltage level of 20V, the voltage level applied to the control gate of a drain-side selection device to generate GIDL might be 12V. The selected data line might be a data line corresponding to an erase block selected for erasure. The erase block might include all of the memory cells of its strings of series-connected memory cells, such as discussed with reference to FIG. 4A, or the erase block might include only a subset of memory cells of its strings of series-connected memory cells, such as discussed with reference to FIG. 4B. With reference to FIGS. 5A-5B, the selected data line might be any data line 204₀ to 204₇ that is a member of an erase block selected for erasure.

At 605, generation of gate-induced drain leakage (GIDL) might be inhibited from an unselected data line of the plurality of data lines to a channel structure of its respective string of series-connected memory cells. Generation of GIDL might be inhibited by creating a low negative to positive voltage differential between the voltage level to the control gate of a drain-side selection device (e.g., one or more of the GG generator gates 220 and/or drain select gates 212) and the first voltage level. As one example, for a first voltage level of 20V, the voltage level applied to the control gate of a drain-side selection device to inhibit GIDL might be 22V. Inhibiting generation of GIDL from the unselected data line to the channel structure of its respective string of series-connected memory cells might include isolating the unselected data line from the channel structure of its respective string of series-connected memory cells.

The unselected data line might be a data line corresponding to an erase block not selected for erasure. The erase block not selected for erasure might include all of the memory cells of its strings of series-connected memory cells, such as discussed with reference to FIG. 4A, or the erase block not selected for erasure might include only a subset of memory cells of its strings of series-connected memory cells, such as discussed with reference to FIG. 4B. With reference to FIGS. 5A-5B, the unselected data line might be any data line 204₀ to 204₇ that is not a member of an erase block selected for erasure.

At 607, a second voltage level might be applied to a selected access line of the plurality of access lines connected to a respective memory cell of each string of series-connected memory cells of the plurality of strings of series-connected memory cells. With reference to FIGS. 5A-5B, the selected access line might be any access line 202₀ to 202₃ connected to a memory cell selected for erasure. The second voltage level applied to the selected access line might be configured to remove charge from the respective memory cell of the respective string of series-connected memory cells of the selected data line, and might be configured to inhibit removal of charge from the respective memory cell of the respective string of series-connected memory cells of the unselected data line. For example, a gate-to-body voltage differential for a memory cell receiving the second voltage level at its control gate and having a channel structure configured to receive the first voltage level through GIDL generation might be sufficient to remove charge from a data storage structure of the memory cell, while a gate-to-body voltage differential for a memory cell receiving the second voltage level at its control gate and having a channel structure configured to be inhibited from receiving the first voltage level due to inhibiting the GIDL generation might be insufficient to remove charge from a data storage structure of the memory cell. As one example, for a first voltage level of 20V, the access line voltage level might be 0V.

The selected data line might be one of a plurality of selected data lines. Consider the example of the block of memory cells 250 of FIGS. 5A-5B having four erase blocks 470 as described in FIG. 4A, e.g., a first erase block 470₀ including all memory cells of NAND strings 206 selectively connected to data lines 204₀ and 204₁, a second erase block 470₁ including all memory cells of NAND strings 206 selectively connected to data lines 204₂ and 204₃, a third erase block 470₂ including all memory cells of NAND strings 206 selectively connected to data lines 204₄ and 204₅, and a fourth erase block 470₃ including all memory cells of NAND strings 206 selectively connected to data lines 204₆ and 204₇. If the erase block selected for erasure is the first erase block 470₀ in this example, either one of the data lines 204₀ and 204₁ could be the selected data line, while any one of the data lines 204₂ to 204₇ could be the unselected data line. The selected access line might be any one of the access lines 202₀ to 202₃, e.g., any access line 202 connected to a memory cell of the NAND strings 206. In such an embodiment, each control line 219 might receive a voltage level configured to inhibit removal of charge from a data storage structure of its corresponding intermediate gates 217, e.g., Vera/2. Alternatively, they might be electrically floated.

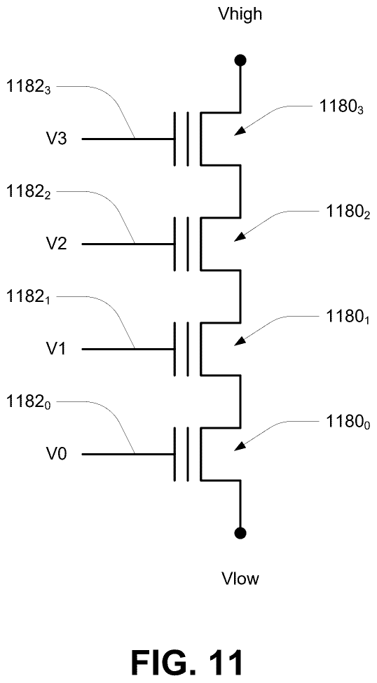

As another example, the block of memory cells 250 of FIGS. 5A-5B might have eight erase blocks 470 as described in FIG. 4B, e.g., a first erase block 470₀ including a first subset of memory cells (e.g., top deck memory cells 360₀) of NAND strings 206 selectively connected to data lines 204₀ and 204₁, a second erase block 470₁ including a first subset of memory cells (e.g., top deck memory cells 360₀) of NAND strings 206 selectively connected to data lines 204₂ and 204₃, a third erase block 470₂ including a first subset of memory cells (e.g., top deck memory cells 360₀) of NAND strings 206 selectively connected to data lines 204₄ and 204₅, a fourth erase block 470₃ including a first subset of memory cells (e.g., top deck memory cells 360₀) of NAND strings 206 selectively connected to data lines 204₆ and 204₇, a fifth erase block 470₄ including a second subset of memory cells (e.g., bottom deck memory cells 360₁) of NAND strings 206 selectively connected to data lines 204₀ and 204₁, a sixth erase block 470₅ including a second subset of memory cells (e.g., bottom deck memory cells 360₁) of NAND strings 206 selectively connected to data lines 204₂ and 204₃, a seventh erase block 470₆ including a second subset of memory cells (e.g., bottom deck memory cells 360₁) of NAND strings 206 selectively connected to data lines 204₄ and 204₅, and an eighth erase block 470₇ including a second subset of memory cells (e.g., bottom deck memory cells 360₁) of NAND strings 206 selectively connected to data lines 204₆ and 204₇. If the erase block selected for erasure is the first erase block 470₀ in this example, either one of the data lines 204₀ and 204₁ could be the selected data line, while any one of the data lines 204₂ to 204₇ could be the unselected data line. The selected access line might be either the access line 202₂ or 202₃, e.g., any access line 202 connected to a memory cell of the top deck of memory cells 360₀ of the NAND strings 206. In such an embodiment, the control lines 219 might receive respective voltage levels configured to isolate the top deck of memory cells 360₀ from the bottom deck of memory cells 360₁, as will be discussed with reference to FIG. 11.

The second voltage level applied to the selected access line might occur concurrently with applying the first voltage level to each data line of the plurality of data lines, generating GIDL from the selected data line to the channel structure of its respective string of series-connected memory cells, and inhibiting generation of GIDL from the unselected data line to the channel structure of its respective string of series-connected memory cells.

The selected access line might be one of a plurality of selected access lines. For example, for an erase block 470 as discussed with reference to FIG. 4A, the plurality of selected access lines might include each access line 202 connected to a memory cell of a NAND string 206 of the block of memory cells 250. Alternatively, for an erase block 470 as discussed with reference to FIG. 4B, the plurality of selected access lines might include each access line 202 connected to a memory cell of the top deck of memory cells 360₀ or the bottom deck of memory cells 360₁ of a NAND string 206 of the block of memory cells 250. The method of FIG. 6 might further be performed concurrently for each selected data line, each unselected data line, and each selected access line.

As used herein, a gate-to-body voltage differential is configured to inhibit removal of charge from a memory cell if it is more likely than not to maintain its present data state. Programming memory cells to respective data states of a plurality of data states might generally result in grouping the memory cells into a plurality of threshold voltage distributions, with one threshold voltage distribution per data state. While these threshold voltage distributions might be separated at the time of programming, they typically will begin to touch or even overlap with time due to charge loss and other phenomena. As such, even the slightest disturb of the charge stored to a data-storage structure of a memory cell could change its data state if it already borders with the threshold voltage distribution of an adjacent data state. However, these outliers represent a small fraction of the total distribution, and might generally be expected to be corrected by error correction protocols.

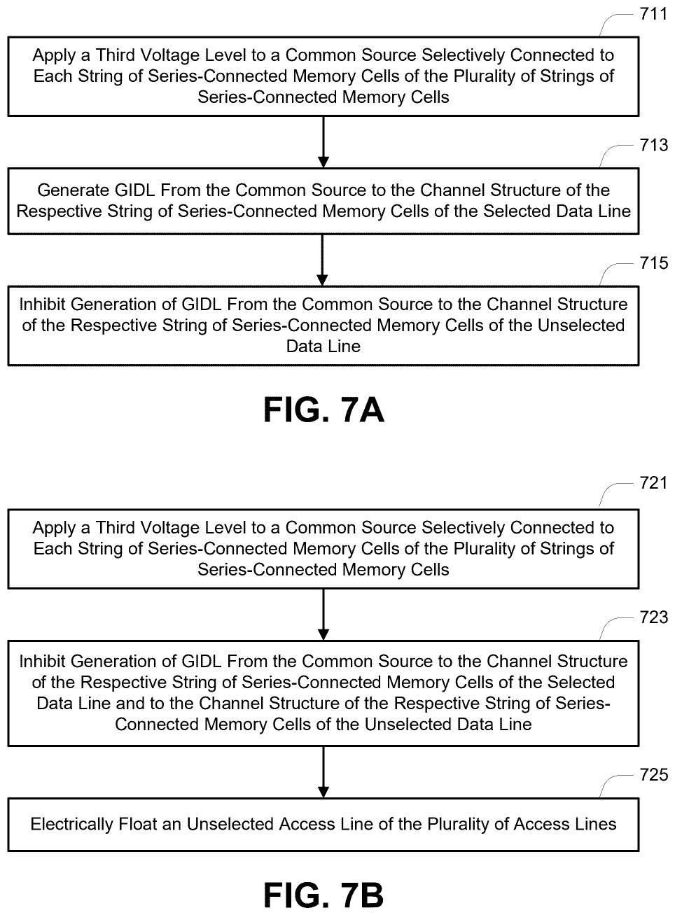

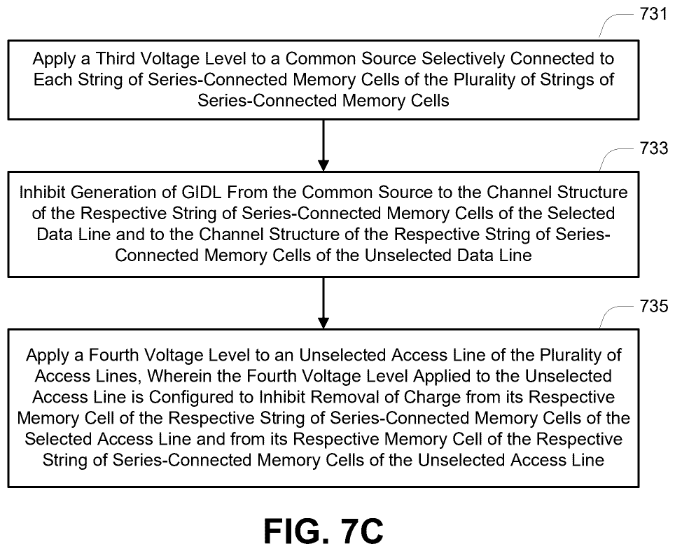

FIG. 7A is a flowchart of a method of operating a NAND memory in accordance with another embodiment. The method might represent actions associated with an access operation, e.g., an erase operation. The method might further be performed in conjunction with the method of FIG. 6. The method might be in the form of computer-readable instructions, e.g., stored to the instruction registers 128. Such computer-readable instructions might be executed by a controller, e.g., the control logic 116, to cause the relevant components of the memory to perform the method. In describing FIG. 7A, common elements between FIG. 6 and FIG. 7A might maintain their same definitions. The method of FIG. 7A might apply to embodiments of the method of FIG. 6 having erase blocks 470 as described with reference to FIG. 4A.

At 711, a third voltage level might be applied to a common source selectively connected to each string of series-connected memory cells of the plurality of strings of series-connected memory cells. For example, with reference to FIGS. 5A-5B, the common source 216 might be selectively connected to the NAND strings 206 through respective nodes 228. Applying the third voltage level to the common source might occur concurrently with applying the first voltage level to the plurality of data lines. The third voltage level might be equal to or different than the first voltage level. Otherwise, the third voltage level might be configured to remove charge from a data storage structure of a memory cell receiving the second voltage level at its control gate and having a channel structure configured to receive the third voltage level through GIDL generation.

At 713, GIDL might be generated from the common source to the channel structure of the respective string of series-connected memory cells of the selected data line. Generating GIDL from the common source to the channel structure of the respective string of series-connected memory cells of the selected data line might occur concurrently with generating GIDL from the selected data line to the channel structure of its respective string of series-connected memory cells.

At 715, generation of GIDL might be inhibited from the common source to the channel structure of the respective string of series-connected memory cells of the unselected data line. Inhibiting generation of GIDL from the common source to the channel structure of the respective string of series-connected memory cells of the unselected data line might occur concurrently with inhibiting generation of GIDL from the unselected data line to the channel structure of its respective string of series-connected memory cells. Inhibiting generation of GIDL from the common source to the channel structure of any one of the strings of series-connected memory cells might include isolating the common source from that string of series-connected memory cells.

The second voltage level applied to the selected access line in 607 of FIG. 6 might occur concurrently with applying the third voltage level to the common source, generating GIDL from the common source to the channel structure of the respective string of series-connected memory cells of the selected data line, and inhibiting generation of GIDL from the common source to the channel structure of the respective string of series-connected memory cells of the unselected data line in FIG. 7A.

FIG. 7B is a flowchart of a method of operating a NAND memory in accordance with another embodiment. The method might represent actions associated with an access operation, e.g., an erase operation. The method might further be performed in conjunction with the method of FIG. 6. The method might be in the form of computer-readable instructions, e.g., stored to the instruction registers 128. Such computer-readable instructions might be executed by a controller, e.g., the control logic 116, to cause the relevant components of the memory to perform the method. In describing FIG. 7B, common elements between FIG. 6 and FIG. 7B might maintain their same definitions. The method of FIG. 7B might apply to embodiments of the method of FIG. 6 having erase blocks 470 as described with reference to FIG. 4B.

At 721, a third voltage level might be applied to a common source selectively connected to each string of series-connected memory cells of the plurality of strings of series-connected memory cells. For example, with reference to FIGS. 5A-5B, the common source 216 might be selectively connected to the NAND strings 206 through respective nodes 228. Applying the third voltage level to the common source might occur concurrently with applying the first voltage level to the plurality of data lines. The third voltage level might be equal to or different than the first voltage level. The third voltage level might be configured to remove charge from a data storage structure of a memory cell receiving the second voltage level at its control gate and having a channel structure configured to receive the third voltage level through GIDL generation. Alternatively, a third voltage level lower than the first voltage level might be applied to the common source, e.g., a voltage level at or near Vss, ground or 0V might be applied to the common source.

At 723, generation of GIDL might be inhibited from the common source to the channel structure of the respective string of series-connected memory cells of the selected data line and to the channel structure of the respective string of series-connected memory cells of the unselected data line. Inhibiting generation of GIDL from the common source to the channel structure of the respective string of series-connected memory cells of the selected data line and to the channel structure of the respective string of series-connected memory cells of the unselected data line might occur concurrently with inhibiting generation of GIDL from the unselected data line to the channel structure of its respective string of series-connected memory cells. Inhibiting generation of GIDL from the common source to the channel structure of any one of the strings of series-connected memory cells might include isolating the common source from that string of series-connected memory cells.

At 725, an unselected access line of the plurality of access lines connected to a respective memory cell of each string of series-connected memory cells of the plurality of strings of series-connected memory cells might be electrically floated. The unselected access line might be any access line 202₀ to 202₃ not connected to a memory cell selected for erasure. For example, if the selected access line is one of the access lines 202₂ and 202₃ corresponding to the top deck of memory cells 360₀ in FIGS. 5A-5B, the unselected access line might be either the access line 202₀ or 202₁ corresponding to the bottom deck of memory cells 360₁, and vice versa.

The unselected access line might be one of a plurality of unselected access lines, and might include any access line connected to a memory cell of a NAND string 206 of the block of memory cells 250 that is not selected for erasure. The method of FIG. 7B might further be performed concurrently for each unselected access line.

The second voltage level applied to the selected access line in 607 of FIG. 6 might occur concurrently with applying the third voltage level to the common source, inhibiting generation of GIDL from the common source to the channel structure of the respective string of series-connected memory cells of the selected data line and to the channel structure of the respective string of series-connected memory cells of the unselected data line, and electrically floating the unselected access line of FIG. 7B.

FIG. 7C is a flowchart of a method of operating a NAND memory in accordance with another embodiment. The method might represent actions associated with an access operation, e.g., an erase operation. The method might further be performed in conjunction with the method of FIG. 6. The method might be in the form of computer-readable instructions, e.g., stored to the instruction registers 128. Such computer-readable instructions might be executed by a controller, e.g., the control logic 116, to cause the relevant components of the memory to perform the method. In describing FIG. 7C, common elements between FIG. 6 and FIG. 7C might maintain their same definitions. The method of FIG. 7C might apply to embodiments of the method of FIG. 6 having erase blocks 470 as described with reference to FIG. 4B.

At 731, a third voltage level might be applied to a common source selectively connected to each string of series-connected memory cells of the plurality of strings of series-connected memory cells. For example, with reference to FIGS. 5A-5B, the common source 216 might be selectively connected to the NAND string 206 through respective nodes 228. Applying the third voltage level to the common source might occur concurrently with applying the first voltage level to the plurality of data lines. The third voltage level might be equal to or different than the first voltage level. The third voltage level might be configured to remove charge from a data storage structure of a memory cell receiving the second voltage level at its control gate and having a channel structure configured to receive the third voltage level through GIDL generation. Alternatively, a third voltage level lower than the first voltage level might be applied to the common source, e.g., a voltage level at or near Vss, ground or 0V might be applied to the common source.

At 733, generation of GIDL might be inhibited from the common source to the channel structure of the respective string of series-connected memory cells of the selected data line and to the channel structure of the respective string of series-connected memory cells of the unselected data line. Inhibiting generation of GIDL from the common source to the channel structure of the respective string of series-connected memory cells of the selected data line and to the channel structure of the respective string of series-connected memory cells of the unselected data line might occur concurrently with inhibiting generation of GIDL from the unselected data line to the channel structure of its respective string of series-connected memory cells. Inhibiting generation of GIDL from the common source to the channel structure of any one of the strings of series-connected memory cells might include isolating the common source from that string of series-connected memory cells.

At 735, a fourth voltage level might be applied to an unselected access line of the plurality of access lines connected to a respective memory cell of each string of series-connected memory cells of the plurality of strings of series-connected memory cells. The unselected access line might be any access line 202₀ to 202₃ not connected to a memory cell selected for erasure. For example, if the selected access line is one of the access lines 202₂ and 202₃ corresponding to the top deck of memory cells 360₀ in FIGS. 5A-5B, the unselected access line might be either the access line 202₀ or 202₁ corresponding to the bottom deck of memory cells 360₁, and vice versa. The fourth voltage level applied to the unselected access line might be configured to inhibit removal of charge from the respective memory cell of each string of series-connected memory cells of the plurality of strings of memory cells, regardless of whether they are configured to receive GIDL current or not. The fourth voltage level might be higher than the second voltage level and lower than the first voltage level. As on example, the fourth voltage level might be equal to half the first voltage level, e.g., Vera/2.

The unselected access line might be one of a plurality of unselected access lines, and might include any access line connected to a memory cell of a NAND string 206 of the block of memory cells 250 that is not selected for erasure. The method of FIG. 7C might further be performed concurrently for each unselected access line.

The second voltage level applied to the selected access line in 607 of FIG. 6 might occur concurrently with applying the third voltage level to the common source, inhibiting generation of GIDL from the common source to the channel structure of the respective string of series-connected memory cells of the selected data line and to the channel structure of the respective string of series-connected memory cells of the unselected data line, and applying the fourth voltage level to the unselected access line of FIG. 7C.

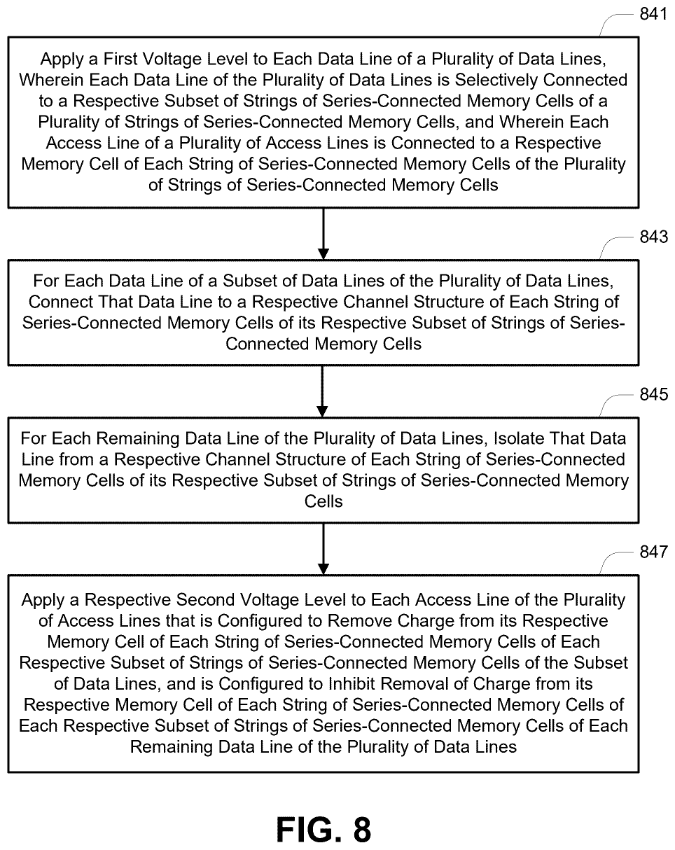

FIG. 8 is a flowchart of a method of operating a NAND memory in accordance with an embodiment. The method might represent actions associated with an access operation, e.g., an erase operation. The method might be in the form of computer-readable instructions, e.g., stored to the instruction registers 128. Such computer-readable instructions might be executed by a controller, e.g., the control logic 116, to cause the relevant components of the memory to perform the method. The method of FIG. 8 might apply to embodiments having erase blocks 470 as described with reference to FIG. 4A.

At 841, a first voltage level, e.g., an erase voltage level (Vera), might be applied to each data line of a plurality of data lines. The plurality of data lines might include each data line of a block of memory cells. For example, with reference to FIGS. 5A-5B, the plurality of data lines might include data lines 204₀ to 204₇. Each data line of the plurality of data lines might be selectively connected to a respective subset of strings of series-connected memory cells of a plurality of strings of series-connected memory cells. For example, with reference to FIG. 5A, the respective subset of strings of series-connected memory cells for data line 204₀ might include NAND strings 206₀₀ to 206₀₇. Each access line of a plurality of access lines might be connected to a respective memory cell of each string of series-connected memory cells of the plurality of strings of series-connected memory cells. For example, with reference to FIGS. 5A-5B, the access lines 202₀ to 202₃ are each connected to a respective memory cell of each string of series-connected memory cells of the plurality of strings of series-connected memory cells of the block of memory cells 250. As one example, the first voltage level might be 20V.

At 843, for each data line of a subset of data lines of the plurality of data lines, that data line might be connected to a respective channel structure of each string of series-connected memory cells of its respective subset of strings of series-connected memory cells. Connecting a data line to a channel structure of a string of series-connected memory cells might include generating GIDL from that data line to that channel structure of the string of series-connected memory cells. The subset of data lines might be a proper subset of data lines of the plurality of data lines, e.g., containing at least one data line and less than all data lines of the plurality of data lines. The subset of data lines might include all data lines corresponding to an erase block selected for erasure.

At 845, for each remaining data line of the plurality of data lines (e.g., all data lines of the plurality of data lines other than the subset of data lines), that data line might be isolated from a respective channel structure of each string of series-connected memory cells of its respective subset of strings of series-connected memory cells. Isolating a data line from a channel structure of a string of series-connected memory cells might include inhibiting generation of GIDL from that data line to that channel structure of the string of series-connected memory cells.

At 847, a respective second voltage level might be applied to each access line of the plurality of access lines. Each respective second voltage level applied to an access line of the plurality of access lines might be configured to remove charge from its respective memory cell of each string of series-connected memory cells of each respective subset of strings of series-connected memory cells of the subset of data lines, and might be configured to inhibit removal of charge from its respective memory cell of each string of series-connected memory cells of each respective subset of strings of series-connected memory cells of each remaining data line of the plurality of data lines.

The respective second voltage level applied to each access line of the plurality of access lines might occur concurrently with applying the first voltage level to each data line of the plurality of data lines, connecting each data line of the subset of data lines to the respective channel structure of each string of series-connected memory cells of its respective subset of strings of series-connected memory cells, and isolating each remaining data line from the respective channel structure of each string of series-connected memory cells of its respective subset of strings of series-connected memory cells.

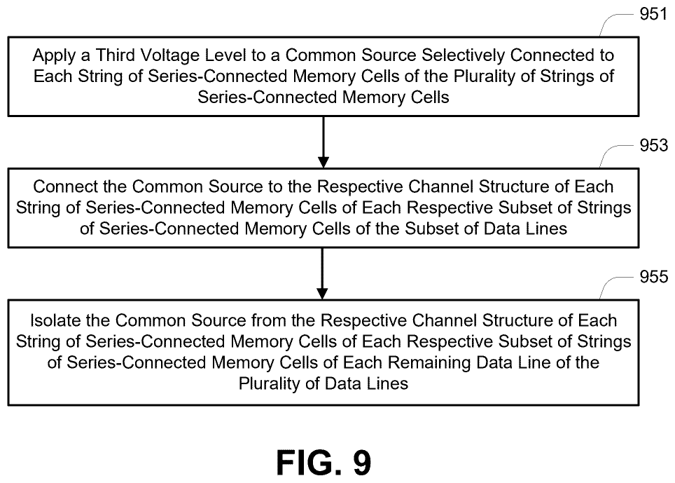

For some embodiments, each string of series-connected memory cells of the plurality of strings of series-connected memory cells might remain isolated from the common source during the method of FIG. 8. For such embodiments, the common source might receive a voltage level lower than the first voltage level, e.g., a voltage level at or near Vss, ground or 0V. Alternatively, the method of FIG. 8 might be performed in conjunction with the method of FIG. 9.

FIG. 9 is a flowchart of a method of operating a NAND memory in accordance with another embodiment. The method might represent actions associated with an access operation, e.g., an erase operation. The method might further be performed in conjunction with the method of FIG. 8. The method might be in the form of computer-readable instructions, e.g., stored to the instruction registers 128. Such computer-readable instructions might be executed by a controller, e.g., the control logic 116, to cause the relevant components of the memory to perform the method. In describing FIG. 9, common elements between FIG. 8 and FIG. 9 might maintain their same definitions.

At 951, a third voltage level further might be applied to a common source selectively connected to each string of series-connected memory cells of the plurality of strings of series-connected memory cells. For example, with reference to FIGS. 5A-5B, the common source 216 might be selectively connected to the NAND strings 206 through respective nodes 228. Applying the third voltage level to the common source might occur concurrently with applying the first voltage level to the plurality of data lines. The third voltage level might be equal to or different than the first voltage level. The third voltage level might be configured to remove charge from a data storage structure of a memory cell receiving the second voltage level at its control gate and having a channel structure configured to receive the third voltage level through GIDL generation.

At 953, the common source might be connected to the respective channel structure of each string of series-connected memory cells of each respective subset of strings of series-connected memory cells of the subset of data lines. Connecting the common source to a channel structure of a string of series-connected memory cells might include generating GIDL from the common source to that channel structure of the string of series-connected memory cells.

At 955, the common source might be isolated from the respective channel structure of each string of series-connected memory cells of each respective subset of strings of series-connected memory cells of each remaining data line of the plurality of data lines. Isolating the common source from a channel structure of a string of series-connected memory cells might include inhibiting generation of GIDL from the common source to that channel structure of the string of series-connected memory cells.

The respective second voltage level applied to each access line of the plurality of access lines in FIG. 8 might occur concurrently with applying the third voltage level to the common source, connecting the common source to the respective channel structure of each string of series-connected memory cells of each respective subset of strings of series-connected memory cells of the subset of data lines, and isolating the common source from the respective channel structure of each string of series-connected memory cells of each respective subset of strings of series-connected memory cells of each remaining data line of the plurality of data lines in FIG. 9.

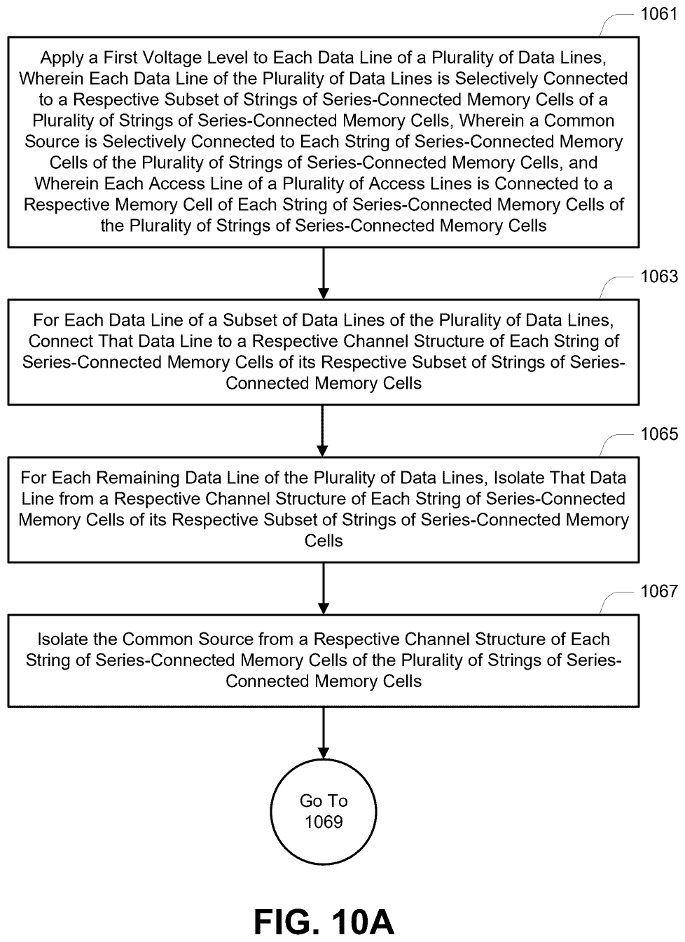

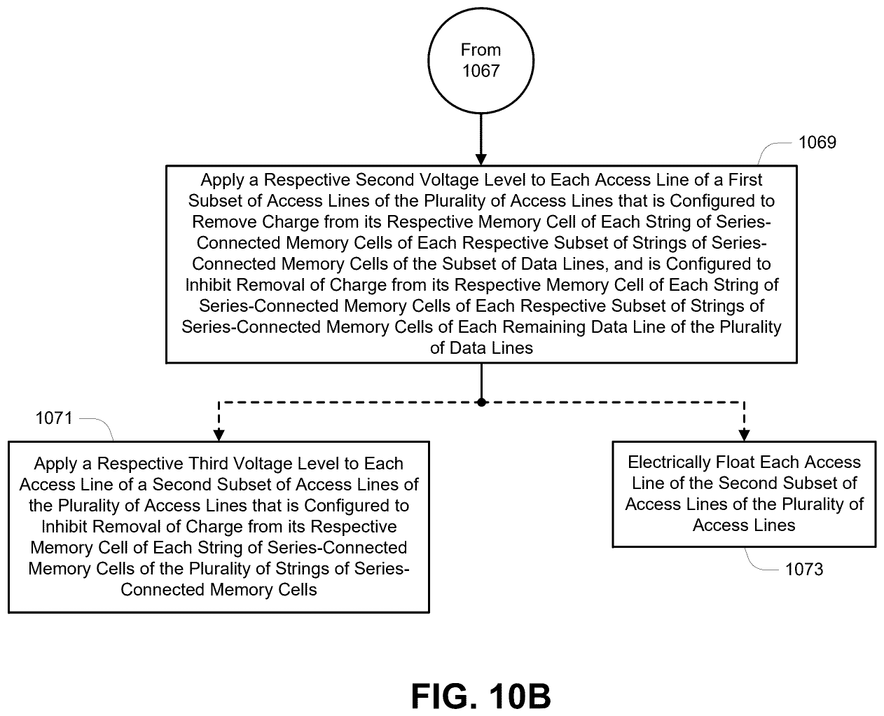

FIGS. 10A-10B are a flowchart of a method of operating a NAND memory in accordance with an embodiment. The method might represent actions associated with an access operation, e.g., an erase operation. The method might be in the form of computer-readable instructions, e.g., stored to the instruction registers 128. Such computer-readable instructions might be executed by a controller, e.g., the control logic 116, to cause the relevant components of the memory to perform the method. The method of FIGS. 10A-10B might apply to embodiments having erase blocks 470 as described with reference to FIG. 4B.

At 1061, a first voltage level, e.g., an erase voltage level (Vera), might be applied to each data line of a plurality of data lines. The plurality of data lines might include each data line of a block of memory cells. For example, with reference to FIGS. 5A-5B, the plurality of data lines might include data lines 204₀ to 204₇. Each data line of the plurality of data lines might be selectively connected to a respective subset of strings of series-connected memory cells of a plurality of strings of series-connected memory cells. For example, with reference to FIG. 5A, the respective subset of strings of series-connected memory cells for data line 204₀ might include NAND strings 206₀₀ to 206₀₇. A common source might be selectively connected to each string of series-connected memory cells of the plurality of strings of series-connected memory cells. Each access line of a plurality of access lines might be connected to a respective memory cell of each string of series-connected memory cells of the plurality of strings of series-connected memory cells. For example, with reference to FIGS. 5A-5B, the access lines 202₀ to 202₃ are each connected to a respective memory cell of each string of series-connected memory cells of the plurality of strings of series-connected memory cells of the block of memory cells 250. As one example, the first voltage level might be 20V

At 1063, for each data line of a subset of data lines of the plurality of data lines, that data line might be connected to a respective channel structure of each string of series-connected memory cells of its respective subset of strings of series-connected memory cells. Connecting a data line to a channel structure of a string of series-connected memory cells might include generating GIDL from that data line to that channel structure of the string of series-connected memory cells. The subset of data lines might be a proper subset of data lines of the plurality of data lines, e.g., containing at least one data line and less than all data lines of the plurality of data lines. The subset of data lines might include all data lines corresponding to an erase block selected for erasure.

At 1065, for each remaining data line of the plurality of data lines (e.g., all data lines of the plurality of data lines other than the subset of data lines), that data line might be isolated from a respective channel structure of each string of series-connected memory cells of its respective subset of strings of series-connected memory cells. Isolating a data line from a channel structure of a string of series-connected memory cells might include inhibiting generation of GIDL from that data line to that channel structure of the string of series-connected memory cells.

At 1067, the common source might be isolated from the respective channel structure of each string of series-connected memory cells of the plurality of strings of series-connected memory cells. Isolating the common source from a channel structure of a string of series-connected memory cells might include inhibiting generation of GIDL from the common source to that channel structure of the string of series-connected memory cells.

At 1069, a respective second voltage level might be applied to each access line of a first subset of access lines of the plurality of access lines. The first subset of access lines might be a proper subset of access lines of the plurality of access lines. The first subset of access lines might include each access line corresponding to one deck of memory cells, e.g., a top deck of memory cells. Each respective second voltage level applied to an access line of the first subset of access lines might be configured to remove charge from its respective memory cell of each string of series-connected memory cells of each respective subset of strings of series-connected memory cells of the subset of data lines, and might be configured to inhibit removal of charge from its respective memory cell of each string of series-connected memory cells of each respective subset of strings of series-connected memory cells of each remaining data line of the plurality of data lines. A respective second voltage level for one access line of the first subset of access lines might be the same as, or different than, the respective second voltage level for a different access line of the first subset of access lines.

Optionally, at 1071, a respective third voltage level might be applied to each access line of a second subset of access lines of the plurality of access lines. The second subset of access lines might be a proper subset of access lines of the plurality of access lines. The second subset of access lines might include each access line corresponding to a different deck of memory cells, e.g., a bottom deck of memory cells. A union of the first subset of access lines and the second subset of access lines might contain all access lines of the plurality of access lines. Each respective third voltage level applied to an access line of the second subset of access lines might be configured to inhibit removal of charge from its respective memory cell of each string of series-connected memory cells of the plurality of strings of series-connected memory cells. A respective third voltage level for one access line of the second subset of access lines might be the same as, or different than, the respective third voltage level for a different access line of the second subset of access lines. Each respective third voltage level might be higher than each respective second voltage level and lower than the first voltage level.

The respective third voltage level applied to each access line of the second subset of access lines might occur concurrently with applying the first voltage level to each data line of the plurality of data lines, applying the respective second voltage level to each access line of the first subset of access lines, connecting each data line of the subset of data lines to the respective channel structure of each string of series-connected memory cells of its respective subset of strings of series-connected memory cells, isolating each remaining data line from the respective channel structure of each string of series-connected memory cells of its respective subset of strings of series-connected memory cells, and isolating the common source from the respective channel structure of each string of series-connected memory cells of the plurality of strings of series-connected memory cells.

Alternatively, at 1073, each access line of the second subset of access lines might be electrically floated. Electrically floating each access line of the second subset of access lines might occur concurrently with applying the first voltage level to each data line of the plurality of data lines, applying the respective second voltage level to each access line of the first subset of access lines, connecting each data line of the subset of data lines to the respective channel structure of each string of series-connected memory cells of its respective subset of strings of series-connected memory cells, isolating each remaining data line from the respective channel structure of each string of series-connected memory cells of its respective subset of strings of series-connected memory cells, and isolating the common source from the respective channel structure of each string of series-connected memory cells of the plurality of strings of series-connected memory cells.

Regardless of whether respective third voltage levels are applied to each access line of the second subset of access lines at 1071, or each access line of the second subset of access lines is electrically floated at 1073, memory cells connected to access lines of the first subset of access lines might be isolated from memory cells connected to access lines of the second subset of access lines, e.g., the top deck of memory cells might be isolated from the bottom deck of memory cells. For example, the control lines 219 might receive respective voltage levels configured to deactivate at least one intermediate gate 217 between the top deck of memory cells and the bottom deck of memory cells. An example of this process will be discussed with reference to FIG. 11.

While the method of FIGS. 10A-10B might apply to erasing an erase block of the top deck of memory cells of a block of memory cells, e.g., the erase block 470₀ of FIG. 4B, a similar method could be used to erase an erase block of a bottom deck of memory cells of a block of memory cells, e.g., the erase block 470₄ of FIG. 4B. For example, instead of applying the first voltage level to each data line of the plurality of data lines at 1061, the first voltage level could be applied to the common source; instead of connecting each data line of the subset of data lines to the respective channel structure of each string of series-connected memory cells of its respective subset of strings of series-connected memory cells at 1063, these channel structures could be connected to the common source; instead of isolating each remaining data line from the respective channel structure of each string of series-connected memory cells of its respective subset of strings of series-connected memory cells at 1065, these channel structures could be isolated from the common source; and instead of isolating the common source from the respective channel structure of each string of series-connected memory cells of the plurality of strings of series-connected memory cells at 1067, these channel structures could be isolated from each data line of the plurality of data lines. In addition, the first subset of access lines might include each access line corresponding to the bottom deck of memory cells, while the second subset of access lines might include each access line corresponding to the top deck of memory cells.

FIG. 11 is a schematic of series-connected transistors for use with embodiments. FIG. 11 depicts four transistors 1180₀ to 1180₃, each having its control gate connected to a respective line 1182₀ to 1182₃. The four transistors 1180 might represent four source select gates 210 and/or GG gates 218, four drain select gates 212 and/or GG gates 220, and/or four intermediate gates 217. Although four transistors 1180 are depicted, fewer or more could be utilized.

Consider the example of isolating a channel structure of a string of series-connected memory cells from the common source, such as described at reference number 1067 of FIG. 10A. In this example, the transistor 1180₃ might represent a first source GG gate 218 nearest the common source 216 and the line 1182₃ might represent a respective control line 222 for the first source GG gate 218, the transistor 1180₂ might represent a second source GG gate 218 and the line 1182₂ might represent a respective control line 222 for the second source GG gate 218, the transistor 1180₁ might represent a first source select gate 210 and the line 1182₁ might represent a respective select line 214 for the first source select gate 210, and the transistor 1180₀ might represent a second source select gate 210 nearest the string of series-connected memory cells and the line 1182₀ might represent a respective select line 214 for the second source select gate 210. Vhigh of FIG. 11 might correspond to the erase voltage level, while Vlow might correspond to 0V or ground, or other voltage level lower than the erase voltage level. A set of voltage levels V0, V1, V2, and V3 might be applied to the lines 1182₀, 1182₁, 1182₂, and 1182₃, respectively, with V0<=V1<=V2<=V3. The voltage level V3 might be higher than or equal to Vhigh, or lower than Vhigh, but near enough to mitigate stress on the transistor 1180₃, and might still activate the transistor 1180₃. By applying successively lower voltage levels to the control gates of the transistors 1180 farther from the common source, deactivation of one or more transistors could be attained. For example, Vhigh might be 20V, V3 might be 22V, V2 might be 14V, V1 might be 6V, and V0 might be −1V, which might be configured to deactivate the transistor 1180₀.

To isolate a channel structure of a string of series-connected memory cells from a data line, such as described at reference number 1065 of FIG. 10A, similar voltage levels might be used. In this example, the transistor 1180₃ might represent a first drain GG gate 220 nearest the data line and the line 1182₃ might represent a respective control line 224 for the first drain GG gate 220, the transistor 1180₂ might represent a second drain GG gate 220 and the line 1182₂ might represent a respective control line 224 for the second drain GG gate 220, the transistor 1180₁ might represent a first drain select gate 212 and the line 1182₁ might represent a respective select line 215 for the first drain select gate 212, and the transistor 1180₀ might represent a second drain select gate 212 nearest the string of series-connect memory cells and the line 1182₀ might represent a respective select line 215 for the second drain select gate 212. In a similar manner, successively lower voltage levels might be applied to the control gates of transistors 1180 farther from the data line, such that at least one of the transistors 1180 is deactivated.

Alternatively, consider the example of isolating a first subset of memory cells (e.g., one deck of memory cells) of a string of series-connected memory cells from its corresponding second subset of memory cells (e.g., different deck of memory cells) of the string of series-connected memory cells. In this example, Vhigh of FIG. 11 might correspond to the erase voltage level applied to the deck of memory cells having an erase block selected for erasure, with the transistor 1180₃ corresponding to the intermediate gate 217 closest to the deck of memory cells containing an erase block selected for erasure. In a similar manner, successively lower voltage levels might be applied to the control gates of transistors 1180 farther from the deck of memory cells containing an erase block selected for erasure, such that at least one of the transistors 1180 is deactivated.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A memory, comprising:
an array of memory cells comprising a plurality of strings of series-connected memory cells; and
a controller for access of the array of memory cells, wherein the controller is configured to cause the memory to:
apply a first voltage level to each data line of a plurality of data lines, wherein each data line of the plurality of data lines is selectively connected to a respective string of series-connected memory cells of the plurality of strings of series-connected memory cells, and wherein each access line of a plurality of access lines is connected to a respective memory cell of each string of series-connected memory cells of the plurality of strings of series-connected memory cells;
generate gate-induced drain leakage (GIDL) from a selected data line of the plurality of data lines to a channel structure of its respective string of series-connected memory cells;
inhibit generation of GIDL from an unselected data line of the plurality of data lines to a channel structure of its respective string of series-connected memory cells; and
apply a second voltage level to a selected access line of the plurality of access lines, wherein the second voltage level applied to the selected access line is configured to remove charge from its respective memory cell of the respective string of series-connected memory cells of the selected data line and is configured to inhibit removal of charge from its respective memory cell of the respective string of series-connected memory cells of the unselected data line.

2. The memory of claim 1, wherein the selected data line is one selected data line of a subset of selected data lines of the plurality of data lines, wherein the unselected data line is one unselected data line of a subset of unselected data lines of the plurality of data lines, wherein the selected access line is one selected access line of a subset of selected access lines of the plurality of access lines, wherein each data line of the plurality of data lines is selectively connected to a respective subset of strings of series-connected memory cells of the plurality of strings of series-connected memory cells, and wherein the controller is further configured to cause the memory to:
for each selected data line of the subset of selected data lines, generate GIDL from that selected data line to a channel structure of each string of series-connected memory cells of its respective subset of strings of series-connected memory cells;
for each unselected data line of the subset of unselected data lines, inhibit generation of GIDL from that unselected data line to a channel structure of each string of series-connected memory cells of its respective subset of strings of series-connected memory cells; and
for each selected access line of the subset of selected access lines, apply a respective second voltage level to that selected access line, wherein its respective second voltage is configured to remove charge from the respective memory cell of each string of series-connected memory cells of each respective subset of strings of series-connected memory cells of each selected data line of the subset of selected data lines, and is configured to inhibit removal of charge from the respective memory cell of each string of series-connected memory cells of each respective subset of strings of series-connected memory cells of each unselected data line of the subset of unselected data lines.

3. The memory of claim 2, wherein a union of the subset of selected data lines and the subset of unselected data lines includes each data line of the plurality of data lines.

4. The memory of claim 1, wherein the controller is further configured to cause the memory to:
apply a third voltage level to a common source selectively connected to each string of series-connected memory cells of the plurality of strings of series-connected memory cells;
generate GIDL from the common source to the channel structure of the respective string of series-connected memory cells of the selected data line; and
inhibit generation of GIDL from the common source to the channel structure of the respective string of series-connected memory cells of the unselected data line.

5. The memory of claim 4, wherein the third voltage level is equal to the first voltage level.

6. The memory of claim 1, wherein the controller is further configured to cause the memory to:
apply a third voltage level to a common source selectively connected to each string of series-connected memory cells of the plurality of strings of series-connected memory cells;
inhibit generation of GIDL from the common source to the channel structure of the respective string of series-connected memory cells of the selected data line and to the channel structure of the respective string of series-connected memory cells of the unselected data line; and
electrically float an unselected access line of the plurality of access lines.

7. The memory of claim 6, wherein the third voltage level is lower than the first voltage level.

8. The memory of claim 1, wherein the controller is further configured to cause the memory to:
apply a third voltage level to a common source selectively connected to each string of series-connected memory cells of the plurality of strings of series-connected memory cells;
inhibit generation of GIDL from the common source to the channel structure of the respective string of series-connected memory cells of the selected data line and to the channel structure of the respective string of series-connected memory cells of the unselected data line; and
apply a fourth voltage level to an unselected access line of the plurality of access lines, wherein the fourth voltage level applied to the unselected access line is configured to inhibit removal of charge from its respective memory cell of the respective string of series-connected memory cells of the selected data line and is configured to inhibit removal of charge from its respective memory cell of the respective string of series-connected memory cells of the unselected data line.

9. The memory of claim 8, wherein the third voltage level is lower than the first voltage level, and wherein the fourth voltage level is lower than the first voltage level and higher than the second voltage level.

10. A memory, comprising:
an array of memory cells comprising a plurality of strings of series-connected memory cells; and
a controller for access of the array of memory cells, wherein the controller is configured to cause the memory to:
apply a first voltage level to each data line of a plurality of data lines, wherein each data line of the plurality of data lines is selectively connected to a respective subset of strings of series-connected memory cells of the plurality of strings of series-connected memory cells, and wherein each access line of a plurality of access lines is connected to a respective memory cell of each string of series-connected memory cells of the plurality of strings of series-connected memory cells;
for each data line of a subset of data lines of the plurality of data lines, connect that data line to a respective channel structure of each string of series-connected memory cells of its respective subset of strings of series-connected memory cells;
for each remaining data line of the plurality of data lines, isolate that data line from a respective channel structure of each string of series-connected memory cells of its respective subset of strings of series-connected memory cells; and
apply a respective second voltage level to each access line of the plurality of access lines that is configured to remove charge from its respective memory cell of each string of series-connected memory cells of each respective subset of strings of series-connected memory cells of the subset of data lines, and is configured to inhibit removal of charge from its respective memory cell of each string of series-connected memory cells of each respective subset of strings of series-connected memory cells of remaining data line of the plurality of data lines.

11. The memory of claim 10, wherein connecting a data line to a respective channel structure of a string of series-connected memory cells comprises generating gate-induced drain leakage (GIDL) from that data line to the respective channel structure of that string of series-connected memory cells.

12. The memory of claim 10, wherein the subset of data lines comprises at least one data line of the plurality of data lines and fewer than all data lines of the plurality of data lines.

13. The memory of claim 10, wherein the controller is further configured to cause the memory to:
apply a third voltage level to a common source selectively connected to each string of series-connected memory cells of the plurality of strings of series-connected memory cells;
connect the common source to the respective channel structure of each string of series-connected memory cells of each respective subset of strings of series-connected memory cells of the subset of data lines; and
isolate the common source from the channel structure of each string of series-connected memory cells of each respective subset of strings of series-connected memory cells of remaining data line of the plurality of data lines.

14. The memory of claim 13, wherein a gate-to-body voltage differential between each respective second voltage level and the third voltage level is configured to remove charge from each memory cell of each string of series-connected memory cells of the plurality of strings of series-connected memory cells.

15. The memory of claim 13, wherein the third voltage level is equal to the first voltage level.

16. A memory, comprising:
an array of memory cells comprising a plurality of strings of series-connected memory cells; and
a controller for access of the array of memory cells, wherein the controller is configured to cause the memory to:
apply a first voltage level to each data line of a plurality of data lines, wherein each data line of the plurality of data lines is selectively connected to a respective subset of strings of series-connected memory cells of the plurality of strings of series-connected memory cells, wherein a common source is selectively connected to each string of series-connected memory cells of the plurality of strings of series-connected memory cells, and wherein each access line of a plurality of access lines is connected to a respective memory cell of each string of series-connected memory cells of the plurality of strings of series-connected memory cells;
for each data line of a subset of data lines of the plurality of data lines, connect that data line to a respective channel structure of each string of series-connected memory cells of its respective subset of strings of series-connected memory cells;
for each remaining data line of the plurality of data lines, isolate that data line from a respective channel structure of each string of series-connected memory cells of its respective subset of strings of series-connected memory cells;
isolate the common source from a respective channel structure of each string of series-connected memory cells of the plurality of strings of series-connected memory cells;
apply a respective second voltage level to each access line of a first subset of access lines of the plurality of access lines that is configured to remove charge from its respective memory cell of each string of series-connected memory cells of each respective subset of strings of series-connected memory cells of the subset of data lines, and is configured to inhibit removal of charge from its respective memory cell of each string of series-connected memory cells of each respective subset of strings of series-connected memory cells of remaining data line of the plurality of data lines; and
electrically float each access line of a second subset of access lines of the plurality of access lines.

17. The memory of claim 16, wherein each access line of the first subset of access lines is connected to its respective memory cells in a top deck of memory cells of a block of memory cells, and wherein each access line of the second subset of access lines is connected to its respective memory cells in a bottom deck of memory cells of the block of memory cells.

18. The memory of claim 17, wherein the controller is further configured to cause the memory to:
isolate memory cells of the top deck of memory cells from memory cells of the bottom deck of memory cells while applying the respective second voltage level to each access line of the first subset of access lines, and while electrically floating each access line of the second subset of access lines.

19. The memory of claim 16, wherein a union of the first subset of access lines and the second subset of access lines includes each access line of the plurality of access lines.

20. The memory of claim 16, wherein data lines of the subset of data lines are interleaved with data lines of the remaining data lines of the plurality of data lines.
